(19) United States
(12) Patent Application Publication
(10) Pub. No.: US 2013/0066572 A1
(43) Pub. Date: Mar. 14, 2013

(54) ASSEMBLED BATTERY

(71) Applicants: Hisanori Terashima, Kanagawa (JP); Tamotsu Fukasawa, Kanagawa (JP)

(72) Inventors: Hisanori Terashima, Kanagawa (JP); Tamotsu Fukasawa, Kanagawa (JP)

(73) Assignee: PUES Corporation, Kanagawa (JP)

(21) Appl. No.: 13/581,522

(22) PCT Filed: Feb. 15, 2011
(86) PCT No.: PCT/JP2011/000826

§ 371 Date: Nov. 9, 2012

(30) Foreign Application Priority Data
Mar. 1, 2010 (JP) 2010-044769

(51) Int. Cl. G01R 31/36; G06F 19/00; H02J 7/00

(52) U.S. Cl. 702/63; 324/430; 320/136

(57) ABSTRACT

The present invention relates to a battery pack constituted by connecting a plurality of unit batteries, in which the route of the signal line is simplified and the manufacturing cost is reduced. The battery pack of the present invention includes means for measuring voltage or the like of a unit battery equipped for every unit battery board and for saving aforesaid measured value, means for transmitting aforesaid saved measured-value to aforesaid battery management unit as a digital signal, and the like, wherein the plurality of unit battery boards and aforesaid battery management unit are connected by a single loop-shaped or double loop-shaped communication channel, and it is constituted so as to carry out transmission and reception of aforesaid measured-value or the like between aforesaid respective unit battery boards and aforesaid battery management unit through aforesaid loop-shaped communication channel.

### TECHNICAL FIELD

The present invention relates to a battery pack constituted by connecting a plurality of unit batteries.

### BACKGROUND ART

There are a lot of cases in which a battery pack formed by combining a plurality of unit batteries is used in accordance with the voltage and electric current capacity requested for the power supply. The unit battery used here covers, starting from a lead battery in old times, a wide-range of a nickel cadmium battery, a nickel hydrogen battery, and then, a lithium ion battery in recent years, in which the characteristics are different depending on the kinds thereof, but the fact one can say commonly is that the battery deteriorates when being charged up to a certain charge amount or more (over-charged), when being discharged up to a certain charge amount or less (over-discharged) and so on; that the deterioration thereof makes progress increasingly when such charge and discharge repeat; and that the lifetime and the reliability of the battery will deteriorate remarkably.

When charging the unit batteries having such characteristics by connecting them in series as a battery pack, there occurs fluctuation in the voltage values at the both ends of the respective unit batteries caused by fluctuation in the self-discharge electric currents and the changes with time (deteriorations) among the respective unit batteries, by fluctuation of charging efficiencies and the like, and there occurs a unit battery which does not become a state of full charge or conversely, there occurs a unit battery which becomes a state of over charge. In addition, also at the time of discharge, fluctuation occurs in the discharge speeds, so that there occurs a unit battery which becomes a state of over charge.

For this reason, in Patent Document 1, there is disclosed a method in which in order to charge-control a plurality of unit batteries, there is installed a battery management unit constituted by an A/D converter circuit and a microcomputer which are common with respect to the plurality of unit batteries; by aforesaid microcomputer, there are detected voltage, temperature, ambient temperature and charge and discharge electric current of each of the respective unit batteries constituting the battery pack; based on the detected unit battery information, the charge state SOC (State of Charge) of the plurality of unit batteries are calculated; and based on the calculated charge state, the individual charge electric currents of aforesaid plurality of unit batteries are controlled.

For the battery pack according to the technology of this Patent Document 1, in a case in which very many unit batteries are used and the output voltage of the battery pack is high, there is employed a method in which caused by the withstand voltage limitation of the electronic circuit constituting the battery management unit, there is provided, for example, a cell-information measurement communication control device for every 8 unit batteries, and the plurality of cell-information measurement communication control devices and the battery management unit are connected by a communication channel (Non-patent Document 1).

In order to realize the technology of the Patent Document 1 actually, it is necessary, between the respective unit batteries and the battery management unit, to provide total three lines, at minimum, of one line of a signal line for voltage sense, of one line of a signal line for battery temperature sense and of one line of a signal line for charge electric current control, in which toward the battery management unit accepting those above, there enter three lines of signal lines from each of the plurality of unit batteries.

For example, when considering a battery pack for driving an automobile in which lithium ion battery cells are made to be unit batteries, it is conceivable that voltage of 500 volts to 700 volts are necessary for driving the automobile with respect to the nominal voltage 3.7 volts of the lithium ion battery, so that the number of unit batteries of the controlled objects becomes around 135 to 190. In this case, it becomes a state in which there will be housed signal lines of (135 to 190)×3=405 to 570 lines in the battery management unit.

Also, as shown in FIG. 1-1 of the Non-patent Document 1, even in case of a method in which a cell-information measurement communication control device is provided for every 8 unit batteries and a plurality of cell-information measurement communication control devices and a battery management unit are connected, it is necessary, for the total configuration, to wire, here and there, the same number of signal lines as those in the above-mentioned case and further, it is necessary to add signal lines for connecting the cell-information measurement communication control devices and the battery management unit.

In this manner, the fact that it is necessary to handle signal lines of a large number of lines is a big problem which becomes an obstacle of cost reduction under the manufacturing of the battery pack for the automobile drive. For the solving means of this problem, there has already been released a technology in which there is provided a connector which can house signal lines of the adjacent battery modules in addition to the respective battery modules (Patent Document 2).
Patent Document 1: Japanese unexamined patent publication H9-294337
Patent Document 2: Japanese unexamined patent publication No. 2007-59088
Non Patent Document 1: “Introduction of Second Generation Lithium Ion Battery Control Unit”, Tokuhiko Morihara, et al., EVS solution 2009, Dec. 17 to 18, 2009, U Thant International Conference Hall of United Nations University, Japan Automobile Research Institute, PP. 108-116

### DISCLOSURE OF THE INVENTION

When using the technology of the Patent Document 2, it is possible to form a plurality of battery modules having a predetermined number of modules as a group of battery modules, to house signal lines from the battery module at an adjacent front position into a connector, and to relay aforesaid signal lines to a battery module at an adjacent rear position, so that it is possible to deal with the treating of the signal lines efficiently, but since a connector which can house all the signal lines of the battery modules constituting the predetermined group must be prepared, it was necessary to prepare an individual connector for every predetermined battery module group. Further, when the number of the predetermined battery modules becomes large and, for example, when the number becomes several hundred, the connector itself becomes large and there was such a problem that it was not possible to mount the connector onto the individual battery module.

The present invention was invented in view of the problem mentioned above and there is disclosed a battery pack constituted by connecting a plurality of unit batteries and including electronic circuit boards (referred to as unit battery boards) equipped with respective unit batteries and a battery management unit common to said plurality of unit battery boards as constituent elements thereof, characterized by comprising, for every individual unit battery board: means for measuring, all of or a portion of, voltage of the equipped unit battery, temperature of said unit battery, ambient temperature of said unit battery and internal resistance of said unit battery, and for saving said measured value; means for transmitting said saved measured value to said battery management unit as a digital signal; and means for receiving and saving a unit battery specifying voltage value which is transmitted as a digital signal from said battery management unit, wherein it is constituted such that aforesaid plurality of unit battery boards and aforesaid battery management unit are connected by a single loop-shaped communication channel or a double loop-shaped communication channel, and through said loop-shaped communication channel, there is carried out transmission and reception of said measured value, said unit battery specifying voltage value and relational control information between said respective unit battery boards and said battery management unit.

The point for solving the problem lies in a configuration in which the number of signal lines from the respective unit battery boards to the battery management unit is made to be minimum. More specifically, it depends on the fact that a function of measuring voltage and temperature is to be employed in the unit battery board and it is made possible to transmit the measurement data from aforesaid unit battery board to the battery management unit by one signal line. For that purpose, it is convenient to use a small size MPU (Micro Processor Unit). The small size MPU in recent years includes several numbers of analog to digital converters, and the voltage and the temperature will be measured by using this function.

Cell-information (battery voltage, battery temperature, battery ambient temperature and battery internal resistance) which is necessary in the unit battery board is obtained and digitized, so that for the information giving and receiving with respect to the battery management unit, the information is transmissible as digital data, it is easy to DC-isolate between the unit battery board and the battery management unit, and the possibility, in which the problem of the withstand-voltage limitation in the battery management unit can be resolved, is large. Therefore, it becomes unnecessary, on an occasion of connecting the battery management unit and the unit battery board, to install a cell-information measurement communication control device for every eight boards of the unit battery boards such as shown in the Non-patent Document 1.

However, if employing a configuration in which the battery management unit and the respective unit battery boards are connected by individual lines in a star shape, one line for up and down respectively and total two signal lines are necessary at minimum for every unit battery board for the information giving and receiving, so that there occurs a problem that the battery management unit must house the signal lines twice the number of the unit battery boards and DC isolation circuits are necessary as many as the number thereof, in which the cost burden is still large.

In order to avoid a configuration in which this large number of signal lines is wired here and there, there is also a method in which a radio transmission and reception function is employed for the respective unit battery boards, but this is not necessarily effective when considering the cost burden. Then, supposing that the serial communication interface, which the small size MPU includes, is to be utilized efficiently, there are two problems. (1) A low cost small size MPU is designed to include at most a single transmission port and a single reception port, in which parallel transmission of information cannot be achieved, and (2) The respective unit batteries are connected in series, so that there occurs a potential difference for one unit battery between the unit battery boards, and it is not possible to simply link the communication interfaces of the MPU in series all together.

The limitation of the number of ports in the item (1) is to be solved by constituting a loop-shaped communication channel and by achieving efficiency promotion of token ring communication control protocol, and the problem of the potential difference in the item (2) is to be solved by focusing attention on the fact that the “potential difference between the adjacent unit battery boards” is approximately constant and also is not large as much as exceeding the withstand voltage of the semiconductor and by applying a level shift as much as the potential difference of the single unit battery for every unit battery board.

For the battery pack according to the present invention, regardless of the number of unit batteries used for the constitution thereof, the signal lines from the respective unit batteries are two signal lines (in case of single loop-shaped communication channel) or four signal lines (in case of double loop-shaped communication channel), which are composed of a signal line for measured value transmission between the adjacent unit battery boards and a signal line for unit battery specifying voltage value reception, and also the signal lines which the battery management unit houses become two signal lines or four signal lines, which are composed of a signal line for measured value reception and a signal line for unit battery specifying voltage value transmission, in which for the manufacturing of the battery pack, there is an effect that the route of the signal lines to be handled is simplified and a remarkable cost reduction can be realized.

Hereinafter, the present invention will be explained specifically by using drawings. FIG. 1A is a drawing which conceptually shows a whole constitution of a battery pack according to the present invention. A battery pack 1 is a pack in which a battery management unit BMU 100 and a number n of unit battery boards UBB 200/1 to 200/n are connected in a loop configuration by a communication channel 300. Also, the respective unit battery boards UBB 200 are equipped with unit batteries 500, and the unit batteries 500 are connected in series and are connected to a load or a charger by way of an electric power line 400.

It should be noted in this drawing that the information transmission of the single loop-shaped communication channel 300 is shown as being carried out in a direction from one end of the most front-end unit battery board UBB 200/n to the other end of the most rear-end unit battery board UBB 200/1 and this direction is premised also in the explanation hereinafter, but it is allowed to employ a communication channel of the opposite direction and the present invention is never limited by the direction thereof.

Also, FIG. 1B shows a case in which double loop-shaped communication channels 301 and 302 are included. The double loop-shaped communication channel has a redundant constitution in consideration of a failure and it is conceivable that there are provided two lines of communication channels 300. The double loop is not necessarily required under a usual functional explanation, so that in the explanation hereinafter, it is assumed to employ a single loop-shaped communication channel and the explanation of the double loop-shaped communication channel will be omitted essentially.

FIG. 2A is a drawing showing a specific constitutional example of the unit battery boards UBB 200 and an aspect of connections with adjacent unit boards. Each of the unit battery boards UBB 200 includes a unit battery (UB) 500, a micro-processor-unit MPU 201, a driver switch for transmission signal 202, an inverter 204 and a resistor 205 as constituent elements thereof. In FIG. 2A, the adjacent unit battery boards UBB 200 are mutually connected each other by connectors 600 for communication and connectors 700 for electric power.

A signal line 252 of a unit battery board UBB 200/i+1 at the front position is connected to a signal line 251 of a unit battery board UBB 200/i by way of the connector 600 and connected to a reception port Rx of a serial communication port of the MPU 201 in aforesaid unit battery board UBB 200/i through the inverter 204.

Also, a transmission port TX of the serial communication port of the MPU 201 in the unit battery board UBB 200/i is connected to the base electrode of a signal-transmission driver switch 202 and transmits a digital signal onto the signal line 252 by turning the driver switch 202 ON/OFF, in which the aforesaid digital signal is transmitted to an MPU 201 at the rear position by way of the connector 600 and a signal line 251 of a unit battery board UBB 200/i−1 at the rear position.

At that time, the collector electrode of the driver switch 202 in the unit battery board UBB 200/i is connected to the ground reference terminal in a unit battery board UBB 200/i−1 at the rear position by way of a resistor 205 in the unit battery board UBB 200/i−1 at the rear position. Therefore, when the driver switch is OFF, it becomes a state in which twice the voltage of the unit battery voltage is to be applied between the emitter and collector electrodes. In case of employing, for example, a lithium ion battery as the unit battery voltage, the nominal voltage thereof is 3.7 volts, so that 7.4 volts of the twice nominal voltage will be applied, but this is a voltage which the semiconductor driver switch 202 is adequately tolerable. In this manner, whenever the information is transmitted to the adjacent unit battery board UBB at the rear position, it becomes a state in which the potential of the signal level is shifted down as much as one battery of the unit battery.

Also, at that time, the signal waveform of TX is transmitted to the signal line 251 by way of the driver switch and the polarity thereof is reversed and therefore, it is inputted to the Rx terminal by way of the inverter 204. In this manner, the respective unit battery boards UBB are connected in a loop configuration by the signal lines 251 and 252, MPUs 201, driver switches 202 and inverters 204, in which a loop-shaped communication channel 300 is constituted.

Also, it is needless to say that the minus side of the unit battery 500 is supplied to the MPU 201 and others as the ground reference potential inside the aforesaid unit battery board, and the plus side of the unit battery (UB) 500 is supplied to the MPU 201 and others as the power supply.

FIG. 2B shows a case in which the unit battery 500 is constituted by two battery cells 500(1) and 500(2) which are connected in parallel. Generally, since the unit battery is formed by a plurality of battery cells which are connected in parallel depending on the requested electric current capacity, this drawing shows an example thereof, so that the present invention is not to be limited by a case of a parallel connection of two battery cells and it is allowed to employ a configuration in which a plurality of battery cells are connected in parallel or in series and also, are connected by a mixed combination of parallel and series.

FIG. 2C is a drawing which diagrammatically shows a measurement method of necessary measurement items for the SOC calculation by taking the unit battery of FIG. 2B as an example. For the unit battery 500 in FIG. 2B, there are provided two battery cells 500(1) and 500(2), in which the voltage measurement, the temperature measurement and the internal resistance measurement are accomplished by aiming each of the cells and the ambient temperature is measured as a common item.

Specifically, the voltage of the battery cell 500(1) is digitally measured as a potential of aforesaid cell by connecting the plus side of the cell to an analog to digital converter terminal AD1 of the MPU 201 and is stored in a column 3001 of a table 3000 (FIG. 5B) on a primary storage RAM 2012.

Also, for the temperature of the battery cell 500(1), a thermistor 203(1) pasted on aforesaid cell is connected to an AD3 terminal of the MPU 201 and the thermistor potential is measured as a digital value, further, is digitally converted as the temperature, and stored in a column 3003 of a table 3000 (FIG. 5B) on the primary storage RAM 2012.

Further, an electric current sensor 206(1) is connected to an AD6 terminal of the MPU 201 by way of an amplifier 207(1) and the current is measured as a digital value, and further, the value is digitally converted as the internal resistance value and is stored in a column 3006 of the table 3000 (FIG. 5B).

Similarly, the voltage, the temperature and the internal resistance of the battery cell 500(2) are measured and stored in columns 3002, 3004, 3007 of the table 3000 (FIG. 5B) respectively. The ambient temperature is common to the two battery cells, so that it is measured as a digital value by a thermistor 203(p) which is installed, by being hung in the air, in a vacant space in the vicinity of the battery cell of the unit battery board 200 and which is connected to an AD5 terminal of the MPU 201, and further, the value is digitally converted for the ambient temperature and stored in a column 3005 of the table 3000 (FIG. 5B).

FIG. 3 shows a whole constitution when using the unit battery boards shown in FIG. 2A. For the communication channel 300 shown in FIG. 2A, as mentioned before, it becomes a state in which the signal line 252 of the unit battery board UBB 200/i+1 and the signal line 251 of the unit battery board UBB 200/i are connected directly by a single wire and are DC coupled through the connector 600, so that for the potential difference between the most front-end and the most rear-end of the unit battery boards, there are superimposed voltages corresponding to the number of boards. For example, in case of 192 unit batteries and when lithium ion batteries are used, the potential difference thereof reaches 3.7 volts×192=710 volts, so that it is difficult to house the loop-shaped communication channel directly in the battery management unit 100 without DC-isolation.

In order to separate the unit battery boards UBB 200 and the battery management unit BMU 100 DC-currently, there is a system such as trans-coupling, photo-coupling or the like, but for the system having total voltage of over 700 volts in which the unit batteries 500 are connected by 192 batteries in series, the arrangement space for the unit batteries becomes large and the distance between the battery management unit BMU 100 and the group of the unit battery boards UBB 200 becomes necessarily long, so that it is necessary for the transmission therebetween to employ balanced transmission lines and to employ DC disconnection by trans-coupling or the like.

Consequently, as shown in FIG. 3, in order to employ DC-voltage isolations between the unit battery board UBB 200/1 at the most rear-end and the battery management unit BMU 100 and between the unit battery board UBB 200/n at the most front-end and the battery management unit BMU 100, the connections therebetween are carried out by balanced transmission lines using trans-coupling or the like.

Specifically, at both ends of the communication channels therebetween there are installed an U/B converter circuit 801 and a B/U converter circuit 802, which are formed by trans-couplings or the like and balanced transmission lines 310 are constituted. By doing like this, the battery management unit BMU 100 is separated DC-currently from the accumulated high voltage caused by series connection of the unit batteries and the problem of withstand voltage can be solved.

On the other hand, the fact that the input and output signal lines of the unit battery boards UBB 200 are direct-connected by a single wire as shown in FIG. 2A and constitute the unbalanced transmission line 300 in FIG. 3 is just as mentioned above.

FIG. 4 is a drawing showing diagrammatically with regard to how the signal from the battery management unit BMU 100 is transmitted through the unit battery boards UBB 200 and again is returned to the battery management unit BMU 100 when employing the constitution of FIG. 2A and FIG. 3.

The battery management unit BMU 100 transmits digital information to be transmitted by converting it to a balanced signal by using the UB converter 801. This information is received by the BU converter 802 arranged preceding to the unit battery board UBB 200/n at the most front-end and the received signal thereof is converted to an unbalanced signal, and this signal is superimposed on the total voltage of all the unit battery boards UBB 200/1 to 200/n.

More specifically, the signal is inputted as an (n·Er+0/5) volt-signal to the reception port RX of the MPU 201/n. Here, Er denotes the nominal voltage of the lithium battery and +0/5 indicates a signal in which 0 volt is superimposed for the “low” signal and as much as 5 volts is superimposed for the “high” signal.

The transmission data from the MPU 201/n is outputted from the transmission port TX and is inputted to the reception port RX of the MPU 201/n−1 of the unit battery board at the rear position as an {(n−1)·Er+0/5} volt-signal by the driver switch for transmission. In this manner, the information is sequentially transmitted to the unit battery board at the rear position, finally reaches the unit battery board 200/1 as a (0·Er+0/5) volt-signal, and is outputted from the transmission port TX of the MPU 200/1, in which the information is converted to a balanced transmission signal by the UB converter 801 and is transmitted to the BU converter circuit 802 of the battery management unit BMU 100.

In this manner, the unit battery board 200/n at the most front-end and the unit battery board UBB 200/1 at the most rear-end are DC-coupled and therefore, in a case, for example, in which 192 lithium unit batteries are used, the total potential difference therebetween reaches approximately 700 volts, but as mentioned above, it is possible for the information to reach the unit battery board at the most rear-end while being level-shifted as much as the nominal voltage Er of the lithium battery whenever the information data are transmitted to the adjacent unit battery board at the rear position, so that it never happens that the potential difference of 700 volts becomes an obstacle.

FIG. 5A is a constitution diagram of a logic block of the hardware in the micro-processor-unit MPU 201. In the MPU 201, there are included, as constituent elements, a central processing unit CPU 2011, s primary storage RAM 2012, a serial communication interface SCI 2013, a plurality of analog to digital converters ADC 2014, a data output DATA 2015 and a bus 2010.

FIG. 5B shows a table for saving measured values or the like. Here, there is shown a table 3000 with regard to a case in which two battery cells are connected in parallel for each of the unit batteries, in which the measurement of the measured value and storage method thereof are as mentioned above. Also, FIG. 5C shows a table 4000 existing on the primary storage RAM 1002 for storing various kinds of parameter values to be transmitted from the battery management unit BMU 100, in which an equalization voltage value (imported PM value, that is, unit battery specifying voltage value), a TK monitoring timer value, an equalization time are stored in columns 4001 to 4003 respectively.

Also, FIG. 5D shows a constitution of a transmission and reception buffer SRB used for message reception and message transmission. The digital data from the unit battery board UBB 200/i+1 at the front position are imported at the reception port RX, character assembly is carried out in the serial communication interface SCI 2013, and the assembled characters are stored in the transmission and reception buffer SRB on the primary storage RAM 2012 as a reception message.

Also, by the instruction of the central processing unit CPU 2011, the serial communication interface SCI 2013 fetches the reception message of the transmission and reception buffer and relay-transfers it to the unit battery board UBB 200/i−1 at the rear position. In a case in which there is a transmission message in the own unit battery board UBB 200/i, likewise, by the instruction of the central processing unit CPU 2011, the transmission message set on the transmission and reception buffer SRB is fetched and this is transmitted to the unit battery board UBB 200/i−1 at the rear position by way of the transmission port TX.

It is necessary for the transmission and reception buffer SRB to transfer the reception message thereof directly to the unit battery board UBB/i−1 at the rear position while receiving the message from the unit battery board UBB 200/i+1 at the front position, so that the buffer SRB is constituted by a buffer having a round robin format. The transfer of the reception message is carried out by a delay of at most two bytes, so that it is sufficient if two bytes or three bytes are prepared for the buffer capacity thereof, but the transmission message becomes a constitution of maximum 22 bytes (mentioned later in detail), so that the capacity of the transmission and reception buffer is 32 bytes (power of two).

Also, in FIG. 5D, there are shown three registers of a reception byte position counter RBC, a transmission byte position counter SBC and a counter SBN for counting the number of bytes necessary for transmission, which are necessary for the write-in and read-out control of the transmission and reception buffer SRB. Any one of the three register lengths is one byte. The operation thereof will be described later.

Also, it is possible for the central processing unit CPU 2011, by using the data port DATA 2015, to instruct the signal “high” and “low” with respect to the outside through the ports DO0 and DO1. By using this port DO0, ON/OFF control of a discharge circuit which is not shown is carried out. Details thereof will be described later.

FIG. 6A shows a logic block constitution of the hardware in the battery management unit BMU 100. In the BMU 100, there are included, as constituent elements, a central processing unit 1001, a primary storage RAM 1002, a serial communication interface SCI 1003, a U/B converter 801, a B/U converter 802 and a bus 1010.

FIG. 6B shows a transmission buffer and a reception buffer on the primary storage RAM 1002. By the instruction of the central processing unit CPU 1001, the transmission message prepared in a transmission buffer SBM 0/1 on the primary storage RAM 1002 is transmitted to the unit battery board UBB 200/n at the most front-end as a balanced transmission signal from the U/B converter 801 by way of the serial communication interface SCI 1003. Also, the balanced transmission signal from the unit battery board UBB 200/1 at the most rear-end is converted to an unbalanced signal by the B/U converter 802, character assembly is carried out in the serial communication interface SCI 1003, and the assembled characters are stored in a reception buffer RBM 0/1 on the primary storage RAM 1002.

It is sufficient for the transmission buffer SBM 0/1 if it covers the number of longest byte of the transmission command, so that the capacity thereof is selected to be 18 bytes, and the reception buffer RBM 0/1 receives 21-byte responses all together collectively from all the unit battery boards respectively, so that it is necessary for the capacity thereof to be 21 bytes×192=4032 bytes and the capacity thereof is selected to be approximately 4.1 Kbytes including the transmission command, in which either one of the buffers above is a buffer whose area is divided into two areas.

Next, there will be explained functions of the battery management unit BMU 100 and the unit battery boards UBB 200. FIG. 7 and FIG. 8 show formats of messages flowing on the loop-shaped communication channel 300, in which FIG. 7 denotes formats of messages transmitted from the BMU 100 addressed to each UBB 200 and FIG. 8 denotes formats of messages transmitted from the each UBB 200 addressed to the BMU 100.

In FIG. 7 and FIG. 8, “TK”, that is, “token” is described at the tail portion of each of the command frames and response frames, but this only indicates a general concept and “TK” itself is not included in a command frame or a response frame itself. The frame is up to “END”.

FIG. 9 shows a network control signal (generically, CNT) which is used in a communication protocol for communication using the loop-shaped communication channel 300, FIG. 10 shows commands (generically, CMD), FIG. 11 shows various kinds of addresses (generically, ADD), FIG. 12 shows data (generically, DAT), and a table 5000 of FIG. 13 shows details of the status.

FIG. 14 is a drawing showing a principle a message reception and a message transmission of each of the unit battery boards UBB 200. In the reception message (reference numeral (1) of FIG. 14) of the unit battery board UBB 200/n at the most front, there is included a command frame from the BMU 200. The UBB 200/n adds an own response frame to this command, creates a transmission message (reference numeral (2) of FIG. 14) and transmits it to the unit battery board UBB 200/n−1 at the rear position. This command is received by the unit battery board UBB/n−1 at the rear position, and by adding an own response frame thereto, a transmission message (reference numeral (3) of FIG. 14) is created and further, is transmitted to the unit battery board UBB 200/n−2 at the rear position.

While repeating such operations sequentially, it becomes a state in which the response frames from all the unit battery boards 200 are sent-back to the battery management unit BMU 100. In a case in which the battery management unit 200 requests only the response from a specified unit battery board 200/i, any of UBB 200/j (j≠i) other than the aforesaid UBB 200/i does not send-back the response frame, so that it becomes a state in which only the response frame from the UBB 200/i is sent-back.

It should be noted here that “TK” is referred to as “token” and means granting of the transmission right. More specifically, only a node keeping “TK” (in this embodiment, node keeping “TK” within MBU 100 and UBB 200/1 to 200/n) is permitted for the transmission of data. For that purpose, the BMU 100 carries out the transmission by adding “TK” at the rear end of the command frame and grants the transmission right to the unit battery board UBB 200/n at the most front-end (reference numeral (1) in FIG. 14).

Next, the UBB 200/n, which accepted this command, adds the own response frame at the rear side of the command frame, adds “TK” at the further rear side thereof, transmits the message to the unit battery board UBB 200/n−1 at the rear position, and concurrently, carries out the granting of the transmission right (reference numeral (2) in FIG. 14).

Next, by using FIG. 15, FIG. 16 and FIG. 17, there is shown a representative operation sequence of the battery pack 1. FIG. 15 is a sequence diagram of requesting reports of MAC addresses from all the unit batteries 200. When the battery pack 1 is activated for the start-up, the battery management unit BMU 100 transmits, addressed to all the serving unit battery boards UBB 200, a CID command message+TK of the C1-format command frame shown in FIG. 7 so as to report respective MAC addresses toward the unit battery board UBB 200/n (referred to as UBBn and all the same for others) at the most front-end for the collection of IDs (S1001).

The UBBn which received this CID command message analyzes the message, recognizes that the message is a CID command addressed to all the UBBs, sets the own MAC address in the ID column of the R1-format response frame, which is shown in FIG. 8, creates an IDn response, and by inserting it between the END mark of the CID command and the succeeding TK mark, transmits the CID command, the IDn response and TK in this order addressed to the unit battery board UBBn−1 at the rear position (S1002).

The UBBn−1 which received these data similarly creates an IDn−1 response by using the own MAC address and transmits the CID command, the IDn response, the IDn−1 response, TK in this order toward the UBBn−2 at the further rear position (S1003).

There are repeated the same operations sequentially, and the UBB1 at the most rear-end receives the CID command, the IDn response, the IDn−1 response, the ID2 response and TK from the UBB 2 at the front position (S1004), and transmits these data with respect to the BMU by inserting the ID1 response in front of TK (S1005). For the sake of expression by a drawing, the two BMUs are drawn on the right and left sides of the drawing, but this is because the loop-shaped communication channel is illustrated by a development diagram and actually, there is provided only a single BMU.

By S1005, the BMU analyzes the MAC addresses as received IDs of all the UBBs and confirms that they are brand unit battery boards which are permitted to be built-in in the battery pack 1. When the confirmation is obtained, network addresses NADs used inside the battery pack 1 are created corresponding to respective MAC addresses and the respective UBBs are notified by an SNAD command. The aspect thereof is shown at the bottom position in FIG. 15.

At that time, a C2-format command frame is used, NADi is assigned corresponding to each IDi, and the number n of NAD application messages in total are transmitted (S1011 to S1013). Each UBBi imports NADi addressed to itself by the IDi corresponding to the own MAC address and thereafter, by using this NADi, there is carried out the communication between the BMU 100 and the UBB 200/i.

Next, FIG. 16 shows a sequence in a case in which the BMU 100 requests the transmission of data of the measured voltage or the like with respect to the UBB 200. For the request of the measurement data, NADi of the aimed UBBi is set to DA in the C1-format command frame and an RV command is transmitted (S2001). Even if aforesaid RV command is received, the UBBj in which NADi shown in the DA does not coincide with the own NADj transfers the aforesaid command directly to the UBBj−1 at the rear position without doing anything in particular (S2002).

When the UBBi which has the aforesaid NADi receives this RV command frame (S2003), it responds to this frame and sends-back the measured voltage information Vi by an R2-format response frame (S2004). Thereafter, there is nothing added in the UBBj (j≠i) and finally, it becomes a situation in which only the voltage information Vi of the UBBi is sent-back to the BMU.

Also, when transmitting an RV command in which DA is set to be all “0”, all the UBBs react with respect to this command, and the measured voltage information is to be sent-back from all the unit battery boards in the form of RV command, Vn (R2 response n), Vn−1 (R2 response n−1), . . . V1 (R2 response 1) and TK (S2011 to S2016).

Also the report procedures of the measured temperature and the measured internal resistance are essentially identical to the report procedure of the measured voltage, but the processing efficiency is reduced if it is in a situation in which the report data is fetched corresponding to the command and the response message is to be created thereafter, so that regardless of the response message, the position of the measured data on the response frame is fixed (see FIG. 8), there are arranged voltage, temperature and internal resistance in this order from the side which is important and whose reporting frequency is high, and an R4-format response frame is preliminarily prepared such that all data can be sent-back on a steady basis whenever the measurement is carried out. This is referred to as an arranged response frame ARF (Arranged Response Frame) and is prepared on the primary storage RAM 2012.

By sending-back only the voltage at the upper position with respect to the RV command (R2-format response frame), by sending-back both of the voltage and the temperature with respect to the RT command (R3-format response frame), by sending-back all of the voltage, the temperature and the internal resistance with respect to the RR command (R4-format response frame), there is achieved a load reduction of the central processing unit by minimizing the number of processes for every command.

Also, the status information is to be included in all the response frames from R2 to R4 and regarding also this matter, there is employed a configuration in which the information is prepared in advance as the R4 command together with the other measured data for every information collection and the response thereof is to be carried out by the R2-format response frame with respect to the RS command.

Next, FIG. 17 shows a sequence in a case in which the BMU 100 notifies a unit battery specifying voltage value with respect to the respective UBBs 200/i. The voltage equalization of the unit battery 500 is carried out aiming all the UBBs 200, so that the DA of the C1-format command frame is set to be all “0” and an EQL command in which the unit battery specifying voltage value is set to PM for equalization is transmitted toward the UBB 200/n at the most front-end (S2021).

The unit battery board UBB 200/n which received this EQL command analyzes the frame contents thereof and when recognizing that the command is an EQL command addressed to all the UBBs, the MPU 201 of aforesaid UBBn imports the data of the PM inside the frame as a specifying unit battery voltage value for equalization (S2031) and stores the data at the 4200th row as an equalization voltage value of column 4001 of table 4000 on the primary storage RAM 2012 shown in FIG. 5C. Without working over the EQL command frame itself, the command frame is transferred to the UBB 200/n−1 at the rear position.

Hereinafter, each of the UBBs imports the similarly instructed unit battery specifying voltage value as a reference voltage value for equalization, stores the value in the column 4001 of the table 4000 on the primary storage 2012 and transfers the aforesaid EQL command frame to the unit battery board at the rear position, so that it is possible for all the UBBs to import the instructed unit battery specifying voltage value as the reference voltage value for equalization.

The operations with respect to commands SPM1, SPM2 and SPM3 of E type in FIG. 10 are similar to that of the EQL command, in which the parameter values stored in the PMs respectively are imported and stored in the corresponding columns of the tables 4000.

FIG. 19A to FIG. 22 are drawings showing various kinds of operations of the unit battery boards UBB 200 by flowcharts. The commands which the unit battery boards UBB 200 receive from the battery management unit BMU 100 are as shown in FIG. 10, and these commands are just as shown in FIG. 18 when being classified according to the processing types in the unit battery boards UBB 200. As being understood from this classification, the command types A and D create response frames and send them back to the battery management unit BMU 100, so that details thereof will be explained by using flowcharts (FIGS. 20A to 20E and FIGS. 21A to 21E).

Also, the EQL command of type E does not create a response frame, but the process thereof is unique to the battery pack, so that it will be explained in detail by using a flowchart (FIG. 22). For the other types, the processes are closed within all the unit battery boards and the operations thereof are simple, so that detailed explanation thereof will be omitted here.

FIG. 19A and FIG. 19B show process flows common to various kinds of command types. In FIG. 19A, the serial communication interface SCI 2013 executes character assembly of the reception data, completes assembly of one byte, and tries to apply interruption to the central processing unit CPU 2011 at every time when the storage for writing-in aforesaid byte into the transmission and reception buffer SBR is ended, so that the process starts by this action (S5000). The received byte data are written in the transmission and reception buffer SRB on the primary storage RAM 2012 by setting the lower 5 bits of the reception byte position counter RBC (FIG. 5D) as “index”.

In the CPU 2011, the program starts by detecting interruption (S5000), two bytes corresponding to the byte positions br−1 and br on the transmission and reception buffer are read-out with reference to the lower 5 bits “br” of the reception byte counter RBC (S5001), and it is checked, with reference to the contents of a TOP register which is not shown, whether or not there is a reception record of the network control signal “TOP” in the past.

In a case in which there is no reception record (“NO” in S5002), it is analyzed whether or not the aforesaid two bytes are the network control signal “TP” and when it is distinguished that they are “TOP” (“YES” in S5020), the TOP reception registration is carried out (S5021), the serial communication interface 2013 is instructed so as to directly transfer the content of the transmission and reception buffer, that is, “TOP” immediately to the unit battery board UBB 200 at the rear position (S5022), the reception byte position counter RBC is updated as much as “1” for the preparation of the storage of the next reception byte (S5023), and the process is ended (S5030).

In case of “YES” in S5002, the SCI 2013 is instructed so as to transfer the contents of the byte position “br” on the transmission and reception buffer SRB to the own unit battery board UBB (S5003) and next, it is judged whether or not the number of the reception bytes after the “TOP” is even-number or odd-number (S5004), in which in case of “odd-number” (“NO” in S5004), the “TOP” is added as much as “1” (S5005) and the reception byte position counter SBC is added as much as “1” (S5023), and the process is ended (S5030).

FIG. 19B shows a flowchart within S5022 in a case in which the serial communication interface SCI 2013 is instructed for the transfer. The central processing unit CPU 2011 judges first by the counter SBN for counting the number of bytes necessary for transmission whether or not the serial communication interface SCI 2013 is during transmission (S4001).

When confirming that it is not during transmission (“NO” in S4001), the leading head byte position br−1 of the object byte to be transferred on the transmission and reception buffer SRB is set to the transmission byte position counter SBC (S4002), and the value of the counter SBN for counting the number of bytes necessary for transmission is added as much as the number of bytes p (here, p=2 because of corresponding to two bytes of “TOP”) which is to be added and transmitted (S4003).

When judging that it is during transmission (“YES” in S4001), the setting of the reception byte position counter SBC is not carried out and the counter SBN for counting the number of bytes necessary for transmission is added as much as the number of bytes p (here, p=2) which is to be added and transmitted (S4003).

The serial communication interface SCI 2013 which receives the transmission instruction generates an interruption to the central processing unit CPU 2011 when the transmission process of one byte is ended. FIG. 19C shows an operation flow of the central processing unit CPU 2011 after detecting aforesaid interruption.

More specifically, when the interruption is detected, it is judged whether or not there are bytes to be transmitted continuously by inspecting the contents of the counter SBN for counting the number of bytes necessary for transmission (S4101). In a case in which there are no bytes to be transmitted continuously (“YES” in S4101), the operation is ended immediately without carrying out the transmission instruction to the SCI (S4130).

In a case in which there are bytes to be transmitted continuously (“NO” in S4101), the transmission byte position counter is added as much as “1” (S4102), the counter SBN for counting the number of bytes necessary for transmission is subtracted as much as “1” (S4103), the transmission instruction is sent to the SCI (S4104), and the process is ended (S4130).

FIG. 19D shows an operation flow of the serial communication interface SCI 2013 which received the transmission instruction. The process starts by the transmission instruction (S4200), and when the value of the counter SBN for counting the number of bytes necessary for transmission is “0” (“YES” in S4201), it is judged that there is no bytes to be transmitted, an IDLE signal is transmitted with respect to the unit battery board UBB/i−1 at the rear position (S4202), and the operation is ended (S4230).

In a case in which the same counter value is “1” or more (“NO” in S4201), data of the byte position bs on the transmission and reception buffer are read-in by lower 5 bits “bs” of the transmission byte position counter SBC, the data are transferred to the unit battery board UBB/i−1 of the rear position (S4203), and the operation is ended (S4230).

Next, returning to FIG. 19A, in a case in which the received number of bytes after the TOP reception is an even number (“YES” in S5004), the value of the TP is set to be the received number of bytes S (S5006) and various process flows are developed by the S (S5006).

FIG. 20A shows a flow in case of S=2, that is, when the DA having two bytes after the TOP reception is received. The process starts by S=2 (S5100) and it is judged whether or not two bytes of the byte positions br−1 and br of the transmission and reception buffer SRB, which are finished for the read-out in S5001, are all “0” (S5101). When it is “YES” in S5101, that indicates the command is addressed to all the unit batteries UBB, so that the CMD is set to “1” for the registration of command stand-by (S5103). Next, the reception byte position counter is added as much as “1” (S5023) and the process is ended (S5030).

When it is “NO” in S5101, it is judged whether or not it is the own NADi (S5102). When it is “YES” in S5102, the command is addressed to the own unit battery board, so that the command stand-by is registered (CMD=1 in S5103), the reception byte position counter is added as much as “1” (S5023), and the process is ended (S5130). When it is “NO” in S5102, it has nothing to do with the own unit battery UBB, so that the reception byte position counter is added as much as “1” (S5023), and the process is ended without doing anything for others (S5030).

FIG. 20B shows a flow in case of S=4, that is, when four bytes are received after the TOP reception. The process starts by S=4 (S5200), two bytes of the byte positions br−1 and br of the transmission and reception buffer, which are finished for the read-out in S5001, are temporarily stored (TPM) as the PM value of the command, the reception byte position counter RBC is added with “1” (S5023), and the process is ended (S5030).

FIG. 20C shows a flow in case of S=6, that is, when 6 bytes are received after the TOP reception. The process start by S=6 (S5300) and it is judged whether or not it is a state of the command stand-by (S5301). In case of “YES” in S5301, this means that it was in a state of the command stand-by until now, so that it is rewritten to the command acceptance (S5302). Next, two bytes of the byte positions br−1 and br of the transmission and reception buffer, which are finished for the read-out in S5001, are analyzed as the command (S5303).

It becomes a state in which this command analysis selects a process for each of the types shown in FIG. 18. There are shown flowcharts with regard to a process A in FIG. 21A, a process B in FIG. 21B, a process C in FIG. 21C, a process D in FIG. 21D and a process E in FIG. 21E. There will be omitted with regard to processes F and G.

FIG. 21A is a flow at the time of the CID command reception. The process starts by the CID command acceptance (S6000) and in order to create the response frame of the R1 format, the own MAC address, that is, the address having 6 bytes and 48 bits is set to the ID (S6001). The necessary number of transmission bytes p is set to the response frame length 10 bytes of the R1 format (S6002), the reception byte position counter RBC is added as much as “1” (S5023), and the process is ended (S5030).

FIG. 21B is a flow at the time of the reception of the SNAD command. The process starts by the SNAD command acceptance (S6100) and the existence or the nonexistence of the acceptance registration of the SNAD is judged (S6101). The answer “YES” in S6101 shows that it was not accepted in the past, so that the acceptance registration is carried out (S6102), the reception byte position counter RBC is added as much as “1” (S5023), and the process is ended (S5030). The answer “No” in S6101 means “illegal”, so that the TOP is reset (S6103), the reception byte position counter RBC is added as much as “1” (S5023), and the process is ended (S5030).

FIG. 21C shows a flow at the time of the acceptance of PWH, PWSD, ERB, LED, LOF and MSR commands. Any one of the commands instructs the operation inside the unit battery board UBB, so that for the operation of the loop-shaped communication channel, there is no influence after the command acceptance and therefore, detailed explanations thereof will be omitted.

FIG. 21D shows a flow at the time of the acceptance of RS, RV, RT and RR commands. The process starts by the acceptance of each command (S6300), the R2-format response frame is created with respect to the RS and RV commands, and with respect to the RT and RR commands, the response frames of the R3 and R4 formats are created respectively (S6301).

As mentioned above, actually, the data of ST, V1, V2, T1, T2, TP, R1, R2 are obtained and are written-down in the table 3000, and concurrently, the response frame of the R4 format is created on a steady basis as the arranged response frame ARF and when the creation of the response frame of the R2 format is requested, the transcription in a lump from the leading head of the arranged response frame ARF to “V2” is carried out and it is completed by adding “END”, and at the time of the R3 format, the transcription in a lump from the leading head of the ARF to “T2” is carried out and it is completed by adding “END”, and at the time of the R4 format, it is completed by carrying out the transcription in a lump from the leading head of the ARF to “END”. The completed response frame is stored preliminarily on the primary storage RAM 2012 as a transmission stand-by response frame WRF (Waiting Response Frame) (S6302).

Next, the number of bytes p to be added and transmitted is registered (S6303). Here, p=12 in the R2 format, p=18 in the R3 format and p=22 in the R4 format. Next, the reception byte position counter RBC is added as much as “1” (S5023) and the process is ended (S5030).

FIG. 21E shows a flow at the time of acceptance of the commands EQL, SPM1, SPM2 and SPM3. The process starts by the acceptance of aforesaid commands (S6400). The PM value (TPM) which is primarily stored in S5201 is written-down in the corresponding column of the table 4000 (S6401). More specifically, the writing-down and the like are carried out in the column 4001 at the time of the EQL command and are carried out in the column 4002 at the time of the SPM1 command and then, the reception byte position counter RBC is added as much as “1” (S5023) and the process is ended (S5030).

FIG. 20D shows a flow in case of S=8, that is, when receiving eight bytes after the TOP reception. The process starts by S=8 (S5400) and it is judged whether or not two bytes of the byte positions br−1 and br of the transmission and reception buffer, which are finished for the read-out in S5001, are the network control signal “END” (S5401). In case of the “END” acceptance (“YES” in S5401), the “END” acceptance is registered (S5402), the reception byte position counter RBC is added as much as “1” (S5023), and the process is ended (S5030).

In case of “NO” in S5401, it does not mean the reception of “END”, so that it is judged whether or not the “SNAD” was already received (S5401). When the “SNAD” was already received (“YES” in S5410), the SNAD counter is added with “1” (S5411), the reception byte position counter RBC is added as much as “1” (S5023), and the process is ended (S5030).

“NO” in S5410 means “illegal”, so that the TOP acceptance is reset (S5412), the reception byte position counter RBC is added as much as “1” (S5023), and the process is ended (S5030).

FIG. 20E shows a flow in case of S>10, that is, when receiving the ten bytes or more after the TOP reception. The process starts by S>10 (S5400) and it is judged whether or not “END” is accepted (S5501). In a case in which “END” is accepted (“YES” in S5501), it is judged whether or not the two bytes of the byte positions br−1, br on the transmission and reception buffer SRB, which are finished for the read-out in S5001, are “TK” (S5502).

In a case in which they are “TK” (“YES” in S5502), it is judged whether or not there exist the bytes to be added and transmitted by the p value which is set in S6303 (S5503). In a case in which the necessary transmission bytes exist (“YES” in S5503), the two bytes of the byte positions br−1, br on the transmission and reception buffer SRB are cleared and “TK” is imported (S5504), and the imported “TK” is pasted at the rear of the transmission stand-by response frame WRF (S5505).

The pasted WRF+“TK” is written-in on and after the byte position br−1 of the transmission and reception buffer SRB (S5506). The counter SBN for the number of bytes necessary for transmission is added with the response frame length p and the transmission instruction is carried out with respect to the serial communication interface SCI 2013 (S5507), the reception byte position counter RBC is added as much as “1” (S5023), and the process is ended (S5030).

In case of “NO” in S5502 or S5503, it is necessary to continue the frame reception continuously, so that the reception byte position counter RBC is added as much as “1” (S5023), and the process is ended (S5030).

In case of “NO” in S5501, it is judged whether or not the two bytes of the byte positions br−1, br of the transmission and reception buffer, which are already read-in in S5001, are “END” (S5510). In a case in which it is judged as “END” (“YES” in S5510), the “END” reception is registered (S5511), the reception byte position counter RBC is added as much as “1” (S5023), and the process is ended (S5030).

In case of “NO” in S5510, it is judged whether or not it is the third word after the SNAD command reception (S5512). In a case in which it is not the third word (“NO” in S5512), the SNAD counter is added as much as “1” (S5513), the reception byte position counter RBC is added as much as “1” (S5023), and the process is ended (S5030).

In case of the third word after the SNAD command reception (“YES” in S5512), it is judged whether or not the three words (6 bytes, 48 bits) of br from the byte position br−5 of the transmission and reception buffer are the own MAC address (S5514). In a case in which it coincides with the own MAC address (“YES” in S5514), the content of the TPM which is primarily stored in S5201 is set as the own DA (S5515) and thereafter, it is used as the own unit battery board address in the communication with respect to the battery management unit BMP 100.

Next, the SNAD counter is zero-reset, the reception byte position counter RBC is added as much as “1” (S5023), and the process is ended (S5030).

FIG. 22 is a flowchart showing an equalization operation in the unit battery board UBB 200 in a case in which the voltage measurement on a steady basis and the EQL command are accepted and the unit battery specifying voltage value of the PM value is written-down in the column 4001 of the table 4000 as the reference voltage value for the equalization.

The start condition in FIG. 22 lies in the 10 ms timer interruption (S5800). The unit battery board UBB 200 carries out the voltage measurement of the unit battery (UB) 500 when there is the 10 ms timer interruption (S5801), and the measurement result thereof is recorded and saved in the column 3001 or 3002 of the table 3000 (S5802). Next, it is judges by the content of the column 4001 of the table 4000 whether or not it is finished to import the PM value. The column 4001 has been set to all “1” at the initial setting, so that if “NO” is true in S5803, it indicates that the import has been finished.

In this case, there is carried out large and small comparison between the voltage value of the unit battery (UB) 500, which is saved in 3001 or 3002 column of the table 3000, and this imported PM value, that is, the unit the battery specifying voltage value (S5804). In a case in which the saved voltage side is high (“YES” in S5804), the central processing unit CPU 2011 sets the data port DO0 to “high”, thereby turning ON the discharge circuit which is not shown (S5805) and the process is ended (S5820). Thus, aforesaid unit battery board UBB starts the equalization operation.

In case of “YES” in S5803 or in case of “NO” in S5804, the central processing unit CPU 2011 sets the data port DO0 to “low”, thereby turning OFF the discharge circuit which is not shown (S5806) and the process is ended (S5820). Thus, aforesaid unit battery board UBB stops the equalization operation or continues the stop state.

It should be noted that the temperature measurement and the internal resistance measurement other than the battery voltage measurement are carried out by the timer interruption in which, for example, the temperature measurement is carried out by the 1S interruption and the internal resistance measurement is carried out by the 10S interruption. The execution procedure is the same as that in case of the battery voltage measurement, so that detailed explanations thereof will be omitted.

FIG. 23A shows a remote power supply ON/OFF circuit of the battery pack of the present invention. The voltage of the unit battery of the battery pack has a voltage specific for the unit battery, so that a DC-DC converter is used in order to obtain a voltage convenient for stably operating the electronic circuit of the unit battery boards UBB 200.

When the battery pack for an automobile is taken into account and, for example, when the electronic circuit of the UBB is in the operation state when the automobile is not used over a long period of time, the unit battery is consumed during that period, so that there may occur a situation in which the battery pack does not function when it is actually desired to use the automobile. Therefore, it is required that the DC-DC converter can be turned OFF when not in use and also, can be turned ON promptly when necessary.

In FIG. 23A, each of the unit battery boards UBB further includes a DC-DC converter DDC 204 as a constituent element. When the battery pack 1 is in an non-operation state, the PWSD command is transmitted from the battery management unit 100 to the UBB 200 by being addressed to all the unit batteries beforehand, and the data output terminal DO1 of the MPU 201 used for the power supply self-holding is set to “low”.

When the signal transmission from the BMU 100 stops in that state, the signal line 251 of the unit battery board UBBn at the most front-end is maintained to be “low”, the E terminal (Enable terminal) of the DDC 204 becomes “low”, and the DDC 204 becomes in a non-operation state, in which even if the voltage is applied to the input VI, the output VO is zero and the Vcc for the MPU 201 is not supplied, and the UBBn becomes in an OFF state as a whole and there is no electric power consumption at all.

In addition, the Tx terminal of the MPU 201 of the UBBn is also kept to be “low”, so that the UBBn−1 also becomes in an OFF state similarly. The unit battery boards UBB at the rear positions become in OFF states sequentially, in which the OFF state becomes true for the whole battery pack and the electric power consumption becomes zero.

On the other hand, when the signal line 251 of the unit battery board UBBn is changed and held to be “high” by some sort of method, the E terminal of the DDC 204 becomes “high” and the DDC 204 becomes in an operation state in which voltage is supplied to the input VI, so that the DCC 204 generates a voltage at the output VO and the Vcc of the MPU 201 is supplied. The MPU 201 which received the Vcc supply becomes in an operation state and sets the data terminal DO1 to “high” for the power supply self-holding, and the DDC 204 is self-held.

When the UBBn enters into an operation state in this manner, the MPU 201 sets the transmission port Tx to “high” and sets the UBBn−1 at the rear position to be in an operation state. This operation is transmitted sequentially and finally, all the UBBs up to the UBB1 enter into the operation state and the battery pack 1 becomes in an operation state.

Specifically, for example, when a key operation of an automobile is performed and there occurs a necessity of a situation in which the battery pack 1 starts the electric power supply, first, the battery management unit (it is necessary for this unit to be supplied with electricity on a steady basis) transmits a signal of low bit rate (for example, 1 kbps) toward the unit battery board UBBn at the most front-end. This data signal of low bit rate is applied with the U/B and B/U conversions and transmitted to the signal line 251 of the UBBn at the most front-end. Although it is a short time period (several hundred μS), the signal line 251 is held to be “high” caused by this data waveform. This time period is a sufficient time period for the DDC 204 to be awakened and for the MPU 201 to output its self-holding signal.

In this manner, the MPU 201 of the UBBn sets the transmission port TX to “high” when entering into the operation state and makes the UBBn−1 at the rear position shift to an operation state. This operation is repeated sequentially and finally, the UBB1 at the most rear-end enters into an operation state and it is possible to set the battery pack 1 to be in the operation state as a whole.

FIG. 23B shows a method for awaking the DC-DC converter 204 by high speed data information. Even in a case in which the DC-DC converter 204 is turned ON and further, the “high” state for a sufficient time period, during which the MPU 201 is operated and enters into its self-holding, cannot be expected for the signal line 251, in a circuit of FIG. 23B, it is possible to operate the DC-DC converter 204 sufficiently even in a case of a little electric power obtained by DC-restoring a high speed data signal, for example, a data signal waveform of the power supply holding commands continuous for a plurality of number, which are transmitted from the BMU 100 and further, it is possible to turn ON the self-holding circuit of the MPU 201.

The battery management unit BMU 100 continuously transmits a plurality of command frames, which have power supply holding commands PWH, to the UBBn at the most front-end and can confirm the start-up completion of the battery pack 1 depending on the fact that all the unit batteries enter into the operation state by receiving the command frames having aforesaid commands PWH from the UBB1 at the most rear-end.

In case of turning the battery pack 1 off, as mentioned above, the battery management unit BMU 100 transmits a power supply holding releasing command PHSD to the UBBn at the most front-end and thereafter, it is possible to set all the unit batteries 200 to be “OFF” state sequentially by stopping the data transmission. It should be noted that in a case in which the power supply holding releasing command PHSD is not displayed but in a case in which there is no data input for a long time period and the signal line 251 continues the “low” state, it is effective for the MPU 201 to set the self-holding to be “low” by the timer monitoring and to set the DDC 204 so as to be “OFF” preliminarily.

Generally, the unit battery board UBB 200 merely responds to the command from the battery management unit BMU 100, but it operates actively when the communication becomes suspended caused by the fact that the loop-shaped communication channel 300 is in failure. The BMU 100 always transmits the token TK certainly within a certain period of time. It is realized by adding the TK to the commands which output various kinds of instructions to the unit battery board 200 and in a case in which there is nothing to instruct, an idle command IDL is transmitted and the TK is added on the rear side thereof.

Thus, in a case in which the token TK cannot be received within a certain period of time, each of the unit battery boards UBB 200 judges that it is caused by abnormality of the loop-shaped communication channel and creates a token-lost command TKL by itself and transmits it to the unit battery board UBB 200 at the rear position. This TKL command is relayed for every one of the unit battery boards UBB 200 and finally, is communicated to the battery management unit BMU 100, in which it is possible for the BMU to request a service with respect to the maintenance division for the failure of the communication channel.

At that time, by the NADi (see FIG. 8) of the TKL command frame (C3 format command frame) which the BMU 100 received, it can be detected as a failure of the communication channel just before the i^{th} UBB or as the i+1^{th} UBB failure.

When the communication channel is constituted by a double loop-shaped communication channel as mentioned in the beginning and, for example, when a failure is detected in the communication channel 301, it is possible to continue the operation by using the communication channel 302. Also, in case of a board failure of any unit battery board UBB 200/i, the TKL command frame is transmitted from the UBBi−1 through the communication channel 301 and the TKL command is transmitted from the UBBi+1 through the communication channel 302, so that it is possible to judge that the UBBi is in failure, and in addition, in a case in which both the communication channels between the i+1^{th} and i^{th} unit battery boards UBB are in failure, the TKL command is transmitted from the UBBi through the communication channel 301 and the TKL command is transmitted from UBBi+1 through the communication channel 302, so that it is possible to judge that the communication channels between the UBBi and the UBBi+1 are in double failure, in which there is an effect for the restoration of the failure.

It should be noted in the embodiments of the present invention that the battery pack 1 was explained according to an aspect in which the unit batteries 500 are connected in series as shown in FIG. 1A, but the effect of the present invention can be achieved similarly even if employing a constitution in which the battery management unit 100 and the loop-shaped communication channel are connected by connecting the unit battery 500(1) and the unit battery 500(2) in parallel as shown in FIG. 1C, in which such n pairs of parallelly connected unit batteries are connected in series and in which all of the UBBs (1) equipped with the respective unit batteries 500(1) and the UBBs (2) equipped with the respective batteries 500(2) are connected in series respectively independently. It is needless to say, in the present invention, that the number of the unit batteries connected in parallel is not to be limited by the number “two”.

### BRIEF DESCRIPTION OF THE DRAWINGS

FIG. 1A shows a whole constitution (single-loop) of the present invention;

FIG. 1B shows a whole constitution (double-loop) of the present invention;

FIG. 1C shows a whole constitution (parallel and series connection of unit batteries) of the present invention;

FIG. 2A shows a specific constitution of unit battery boards;

FIG. 2B shows a unit battery in which cell batteries are connected in parallel;

FIG. 2C shows various kinds of measurement points of a unit battery;

FIG. 3 shows a balanced transmission line and an unbalanced transmission line;

FIG. 4 shows a principle of level shift;

FIG. 5A shows a hardware block constitution of a unit battery board;

FIG. 5B shows a measurement result table;

FIG. 5C shows a transmission and reception buffer and a related register for the control of a unit battery board;

FIG. 5D shows import PM value tables;

FIG. 6A shows a hardware block constitution of a battery management unit;

FIG. 6B shows transmission and reception buffers for the control of a battery management unit;

FIG. 7 shows command frames;

FIG. 8 shows response frames;

FIG. 9 shows network control signals of communication protocol;

FIG. 10 shows commands of communication protocol;

FIG. 11 shows address of communication protocol;

FIG. 12 shows data of communication protocol;

FIG. 13 shows status information;

FIG. 14 shows a principle of message reception and message transmission;

FIG. 15 shows a sequence diagram of an ID collection command;

FIG. 16 shows a sequence diagram of a voltage report command;

FIG. 17 shows a sequence diagram of a voltage equalization command;

FIG. 18 shows classification of command types;

FIG. 19A shows an operation flowchart of a unit battery board (common portion of command);

FIG. 19B shows an operation flowchart of a unit battery board (transmission instruction unit);

FIG. 19C shows an operation flowchart of a unit battery board (continuous transmission and reception):

FIG. 19D shows an operation flowchart of a unit battery board (serial communication interface unit);

FIG. 20A shows an operation flowchart of a unit battery board (address analyzing unit);

FIG. 20B shows an operation flowchart of a unit battery board (temporary import of PM value);

FIG. 20C shows an operation flowchart of a unit battery board (command analyzing unit);

FIG. 20D shows an operation flowchart of a unit battery board (END detection unit);

FIG. 20E shows an operation flowchart of a unit battery board (TK detection and NAD import unit);

FIG. 21A shows an operation flowchart of a unit battery board (CID command process);

FIG. 21B shows an operation flowchart of a unit battery board (SNAD command process);

FIG. 21C shows an operation flowchart of a unit battery board (UBB inner process command unit);

FIG. 21D shows an operation flowchart of a unit battery board (RV, RT, RR command process);

FIG. 21E shows an operation flowchart of a unit battery board (processing unit of EQL command or the like);

FIG. 22 shows an operation flowchart of a unit battery board (measurement of voltage or the like);

FIG. 23A shows an operation flowchart of a unit battery board (remote power supply ON/OFF: No. 1 thereof); and

FIG. 23B shows an operation flowchart of a unit battery board (remote power supply ON/OFF: No. 2 thereof).

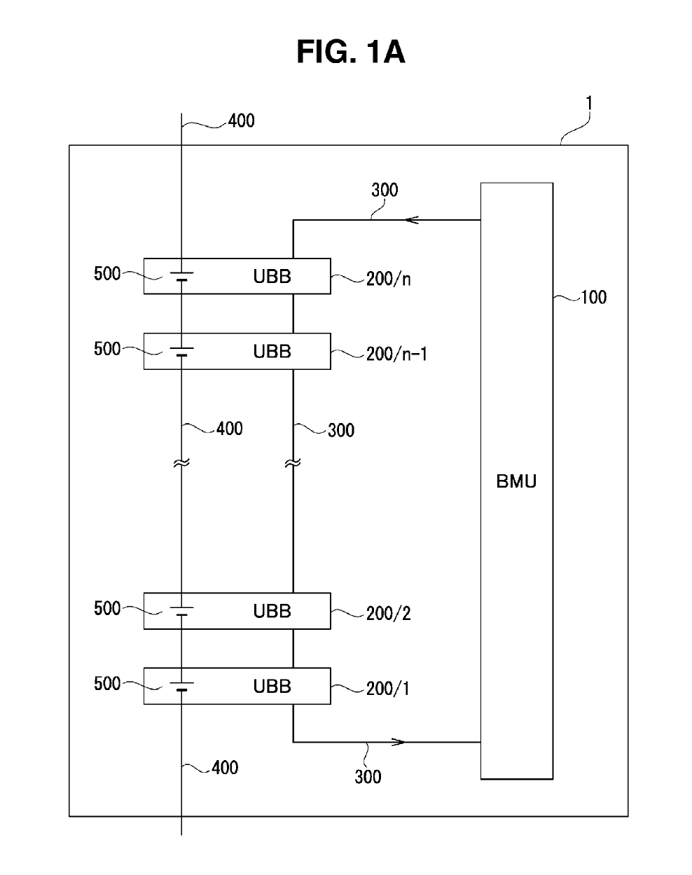

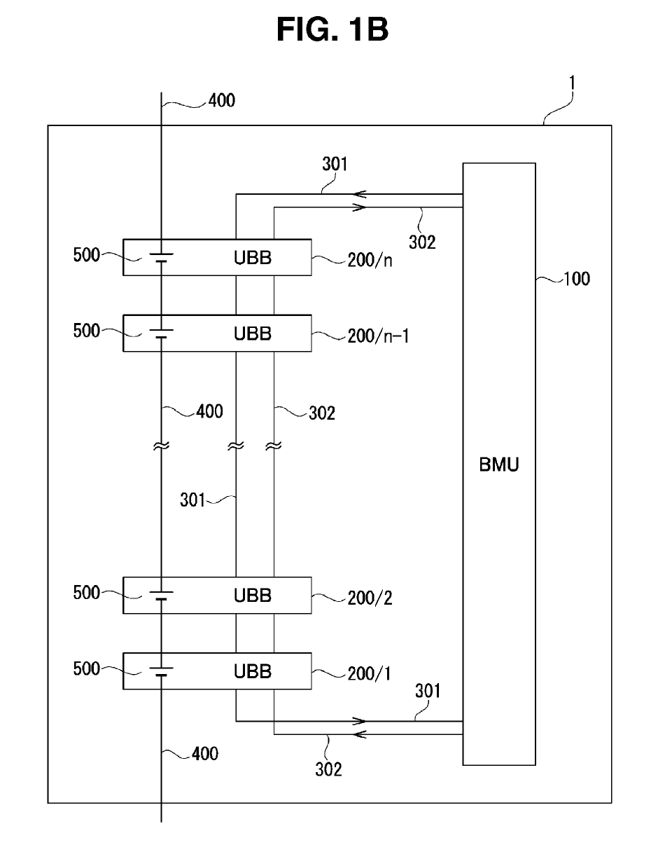

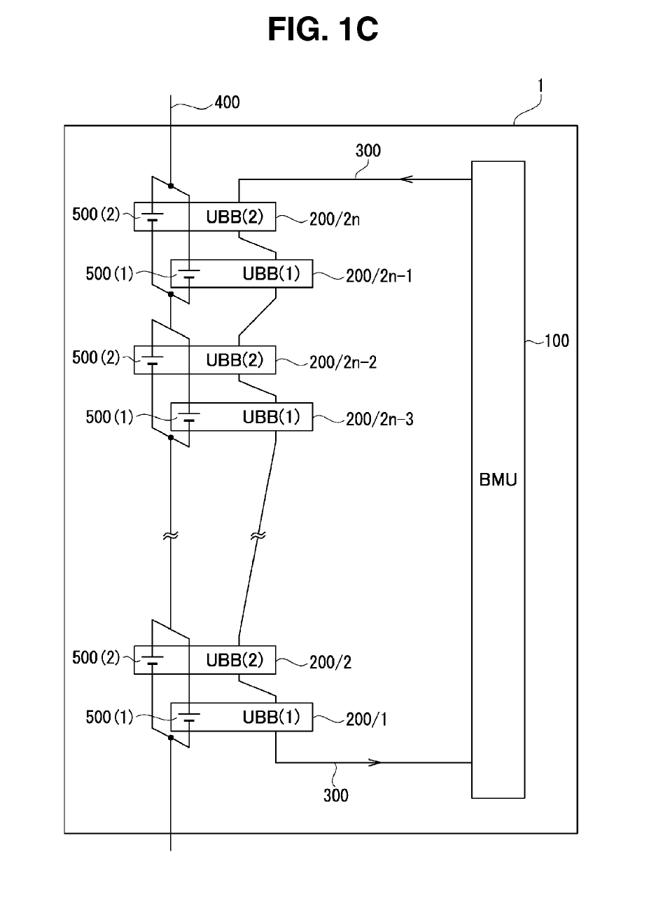

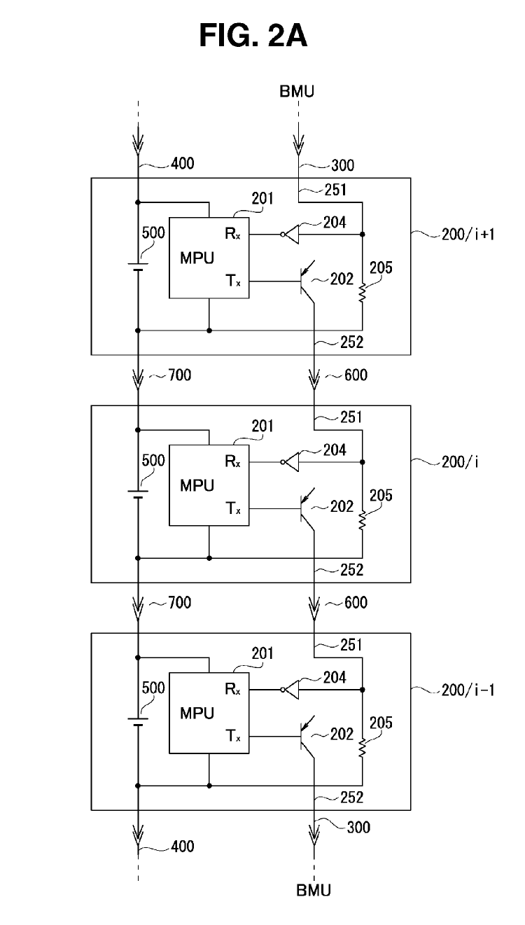

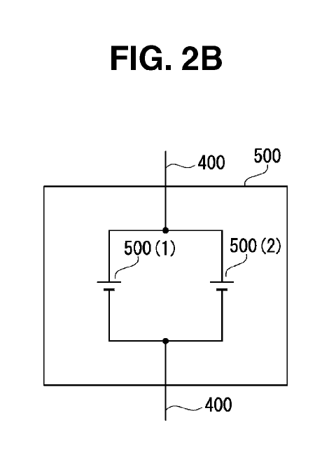

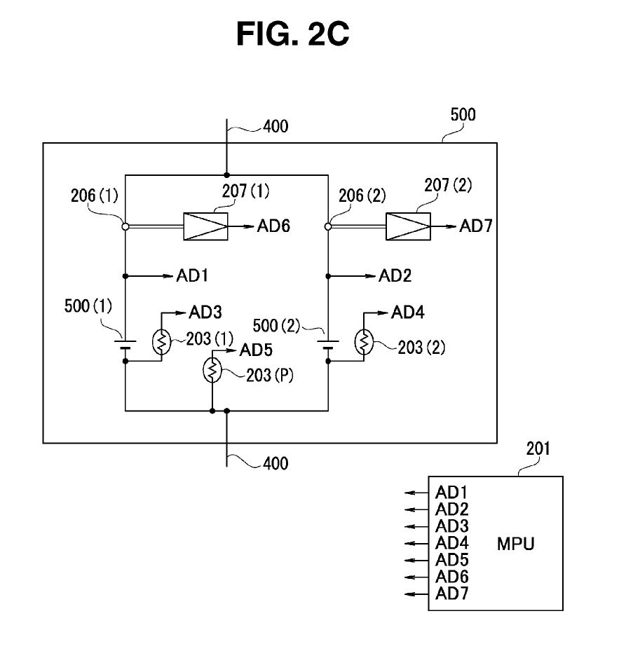

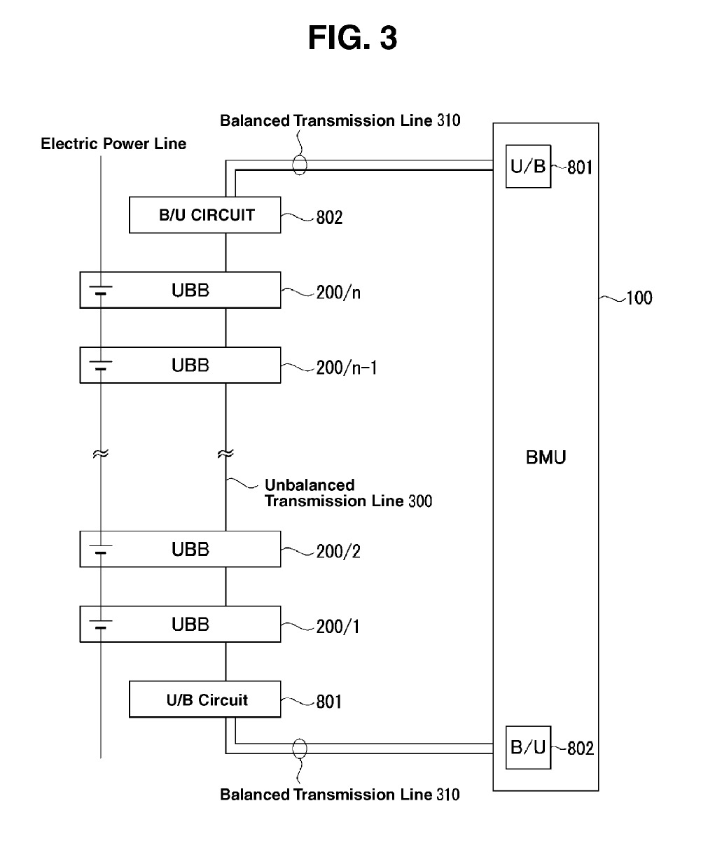

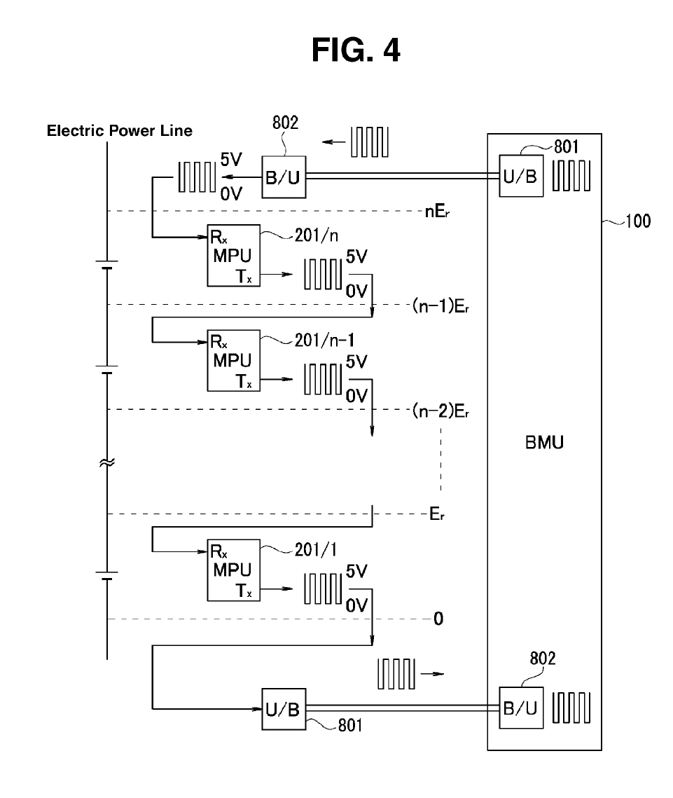

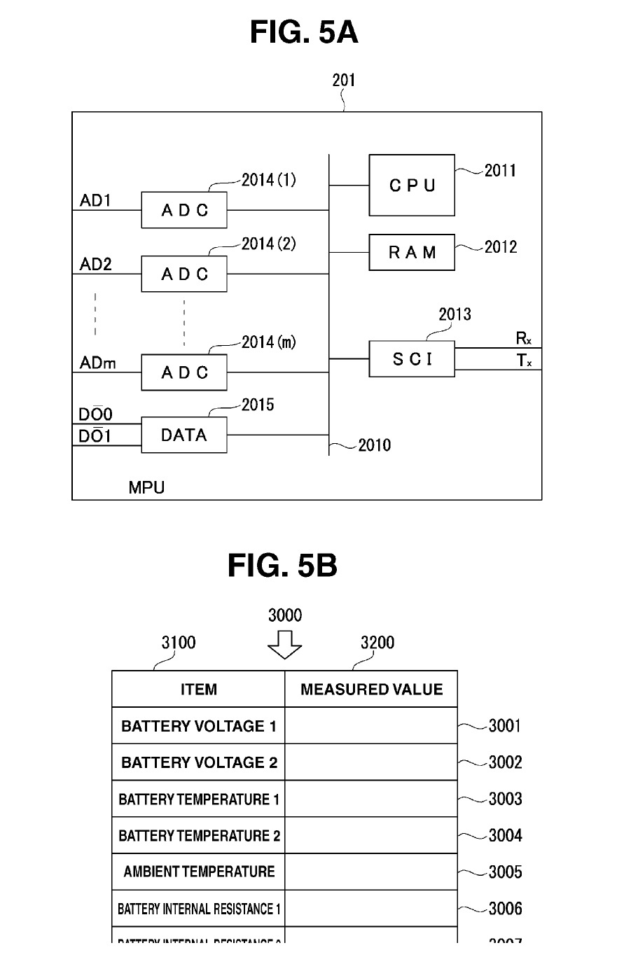

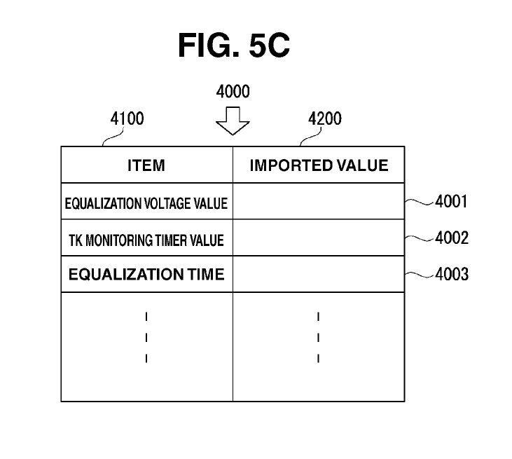

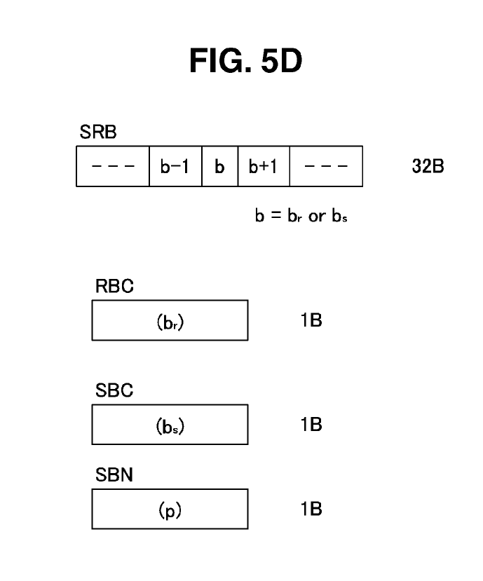

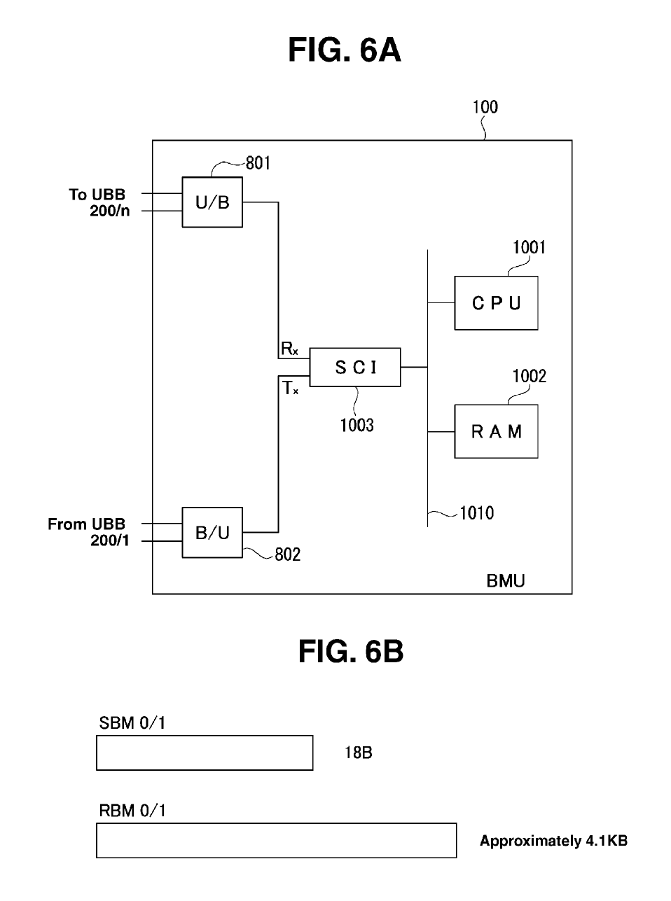

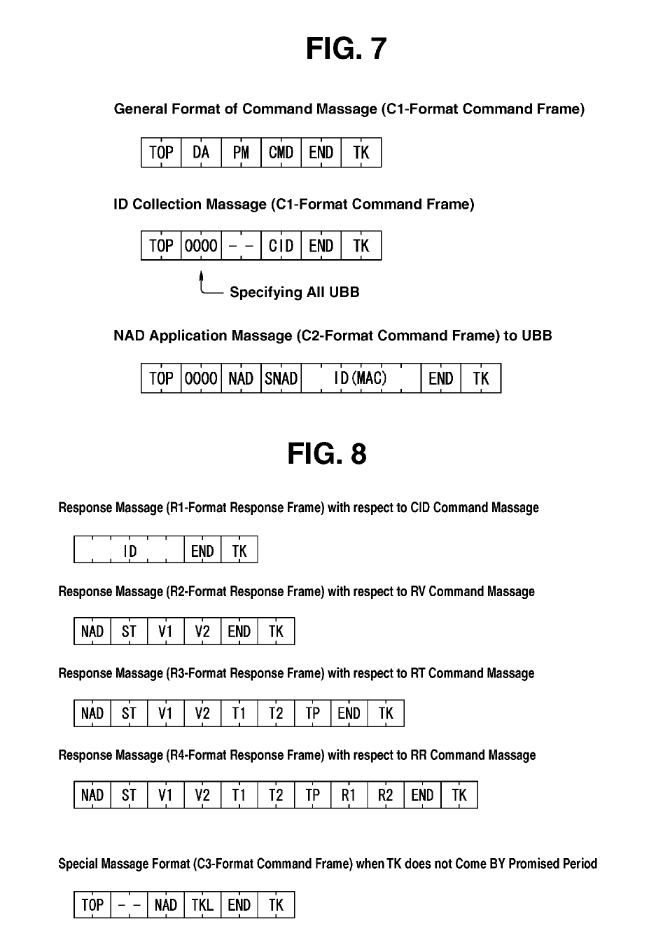

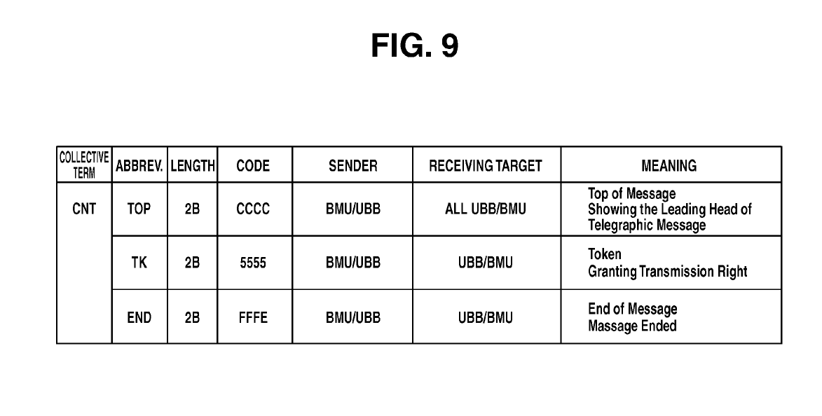

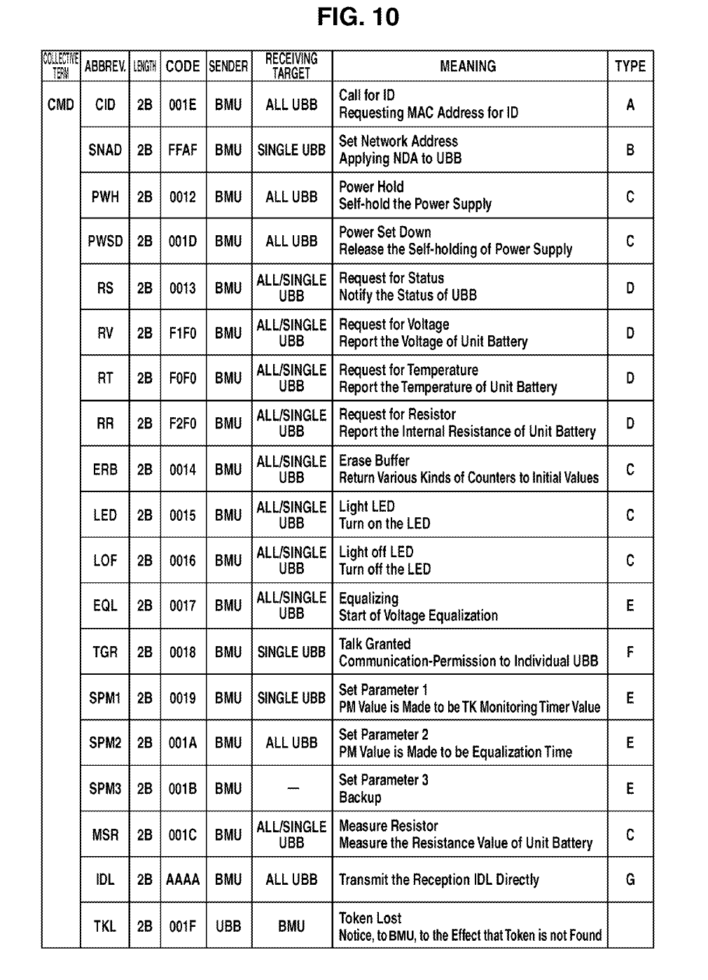

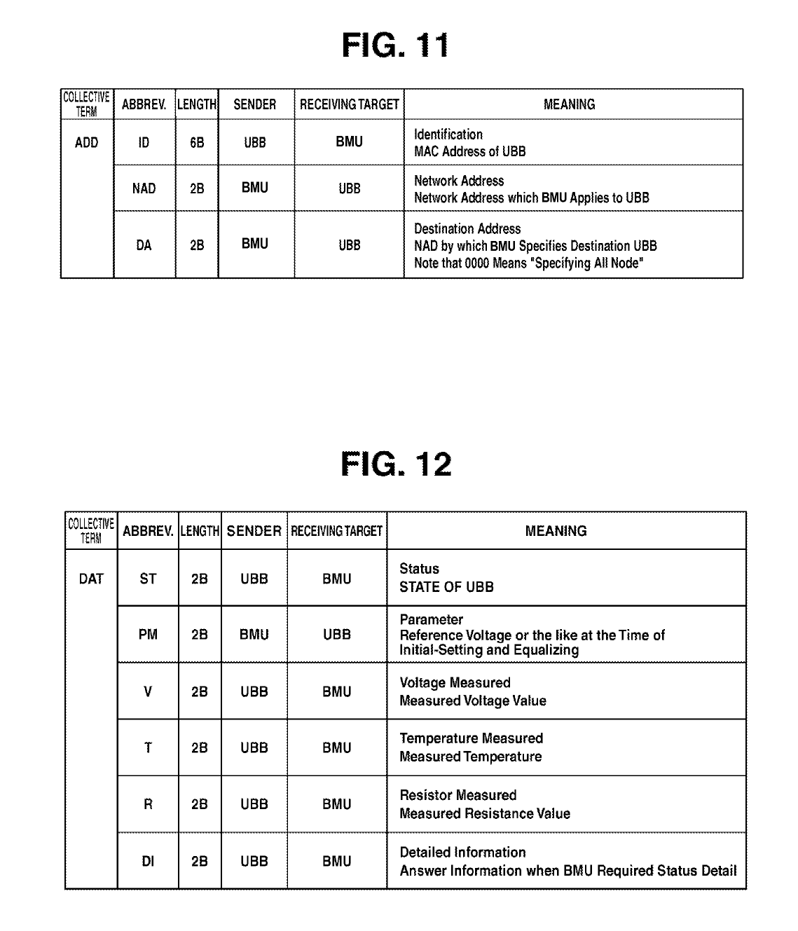

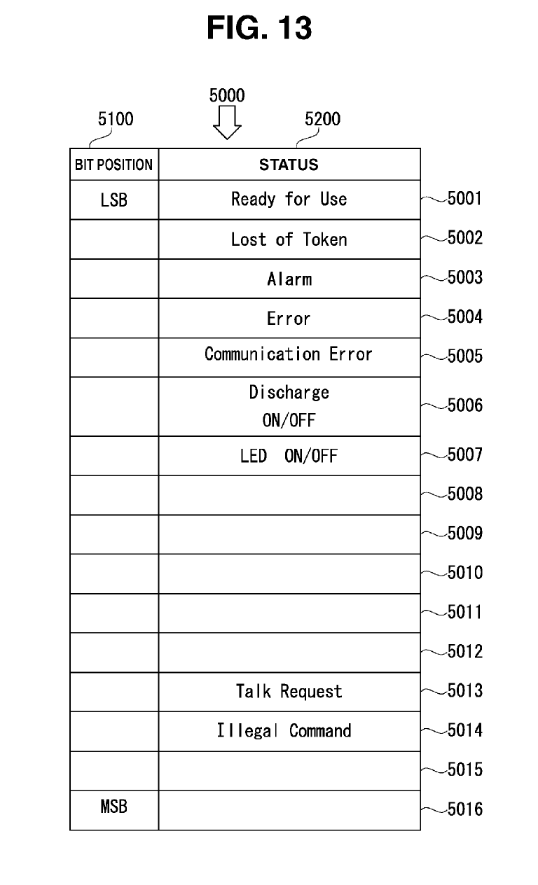

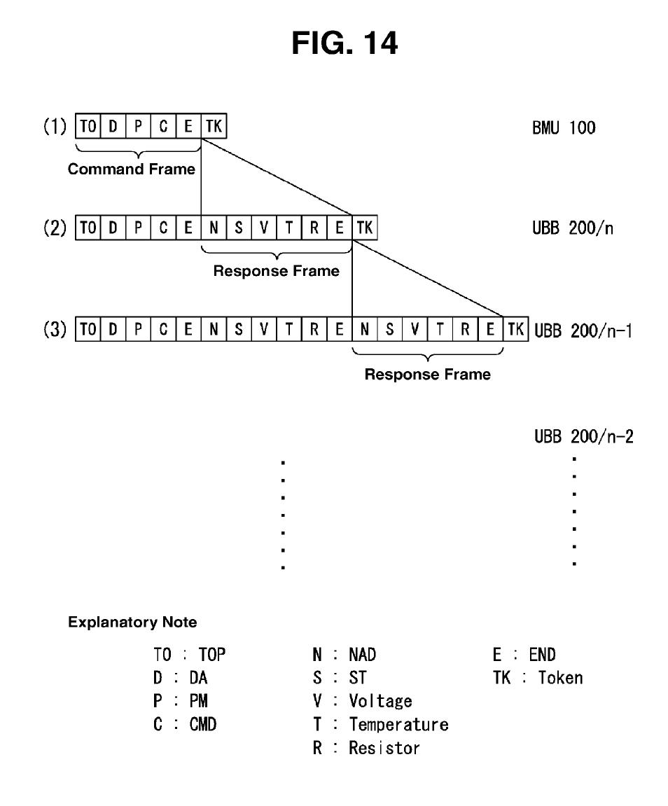

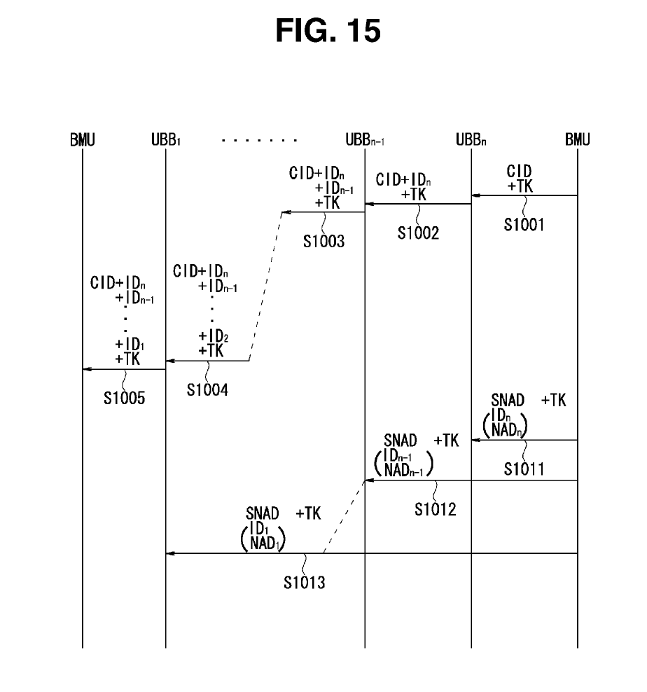

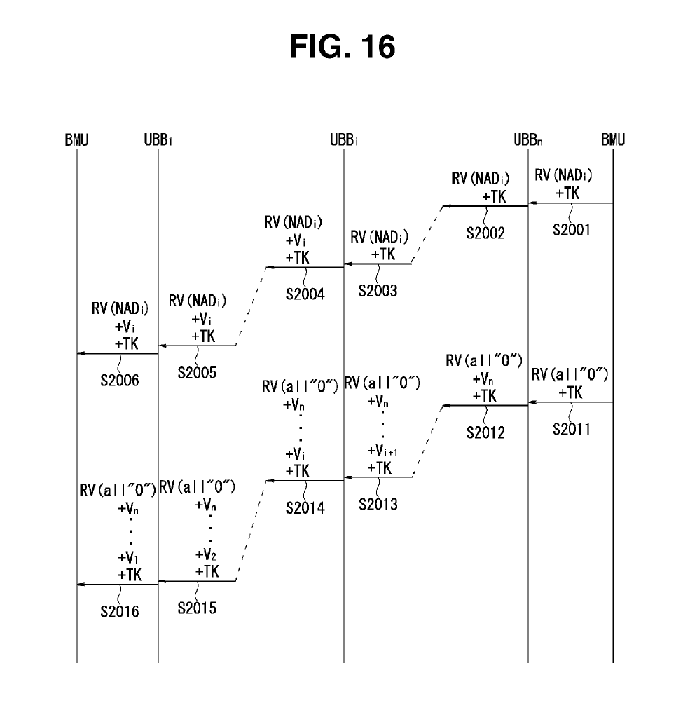

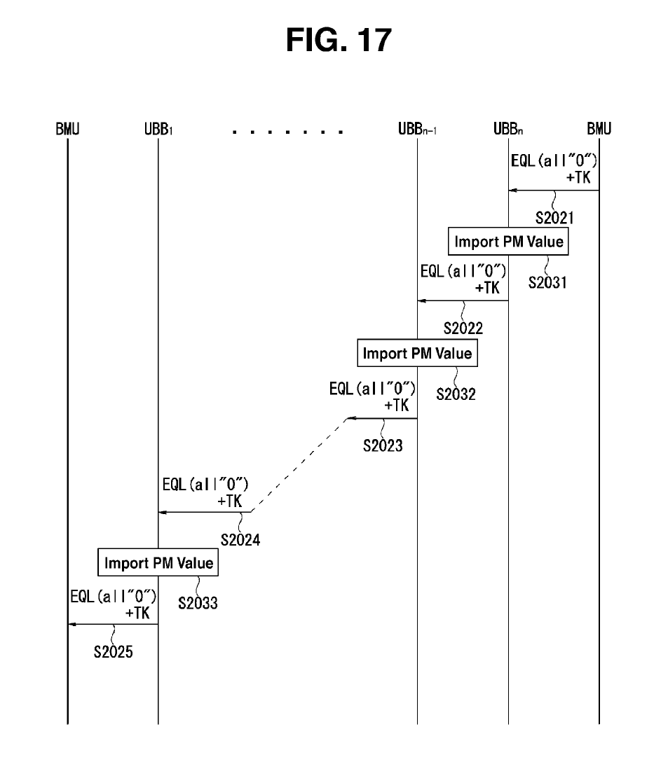

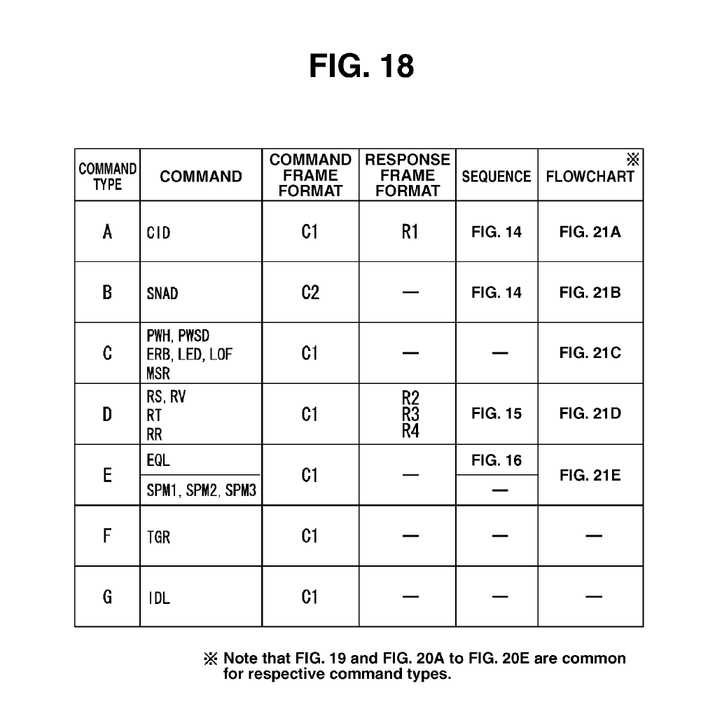

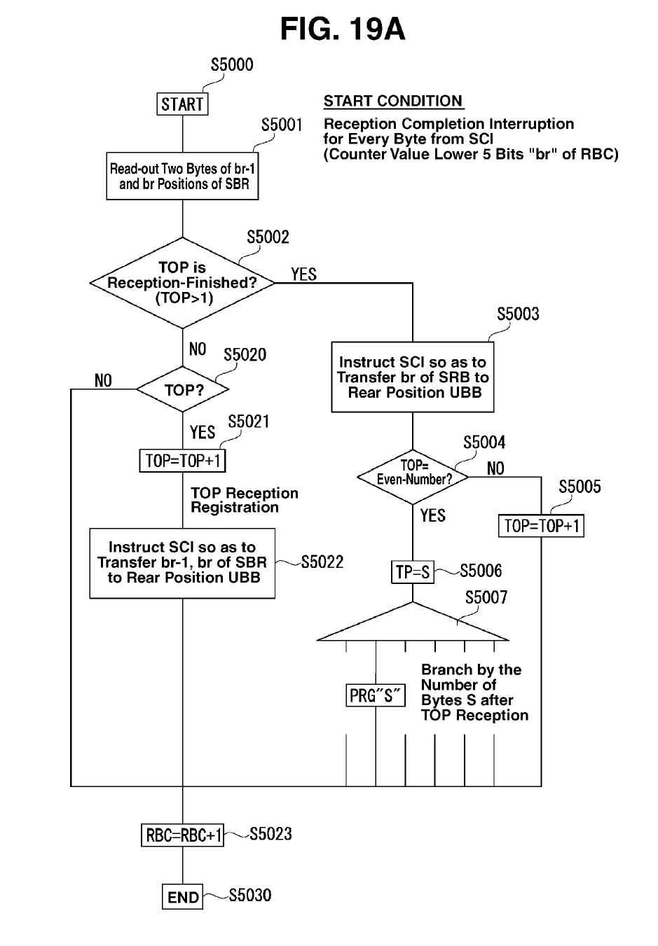

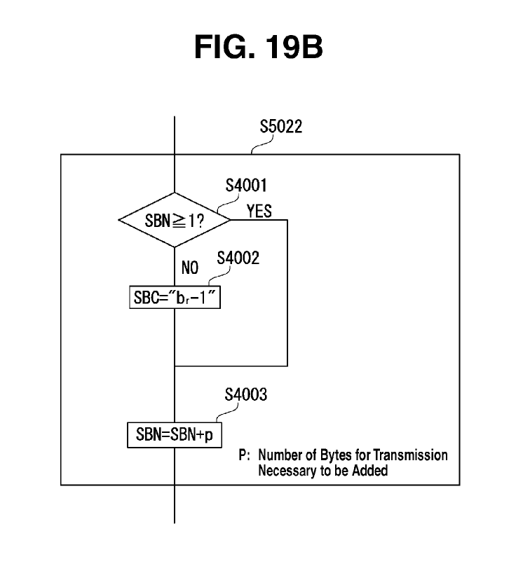

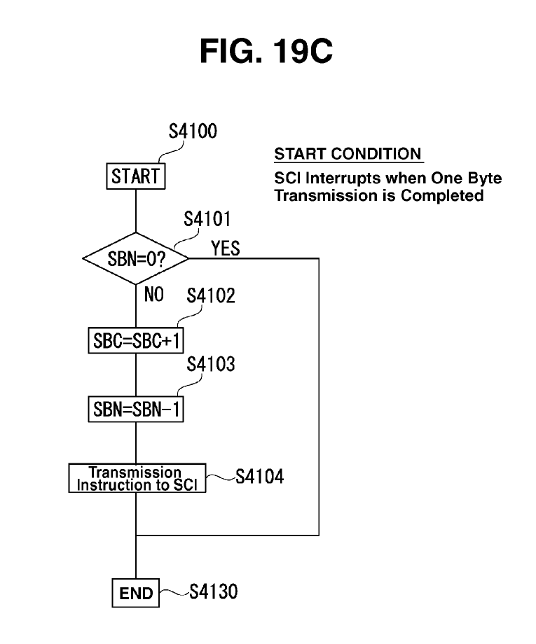

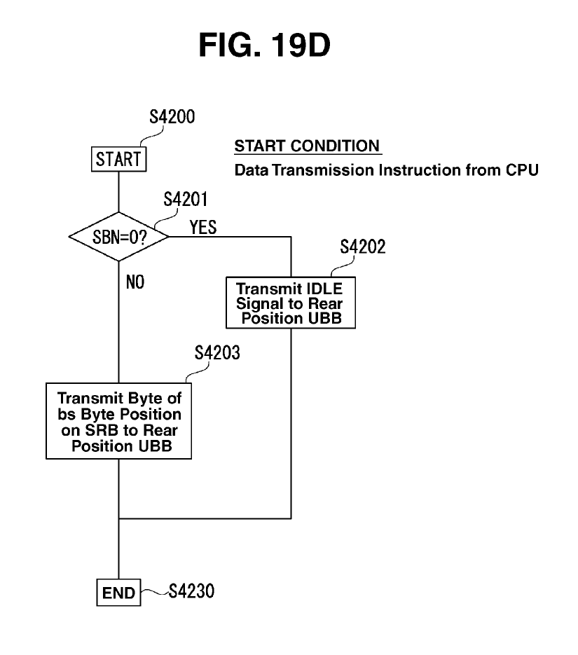

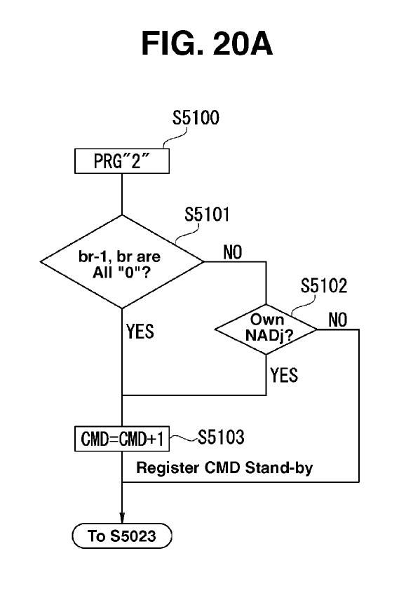

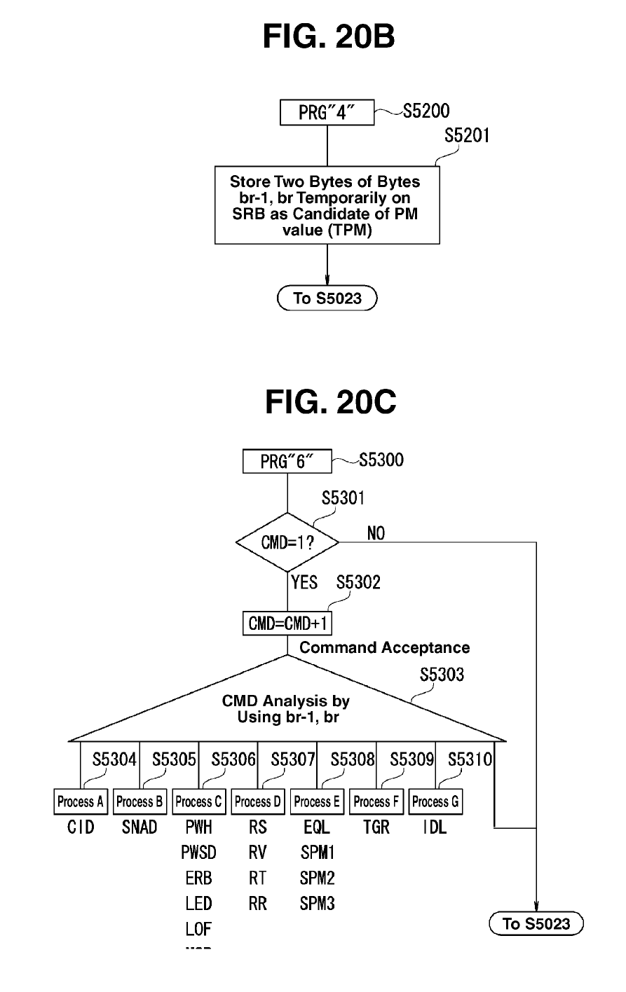

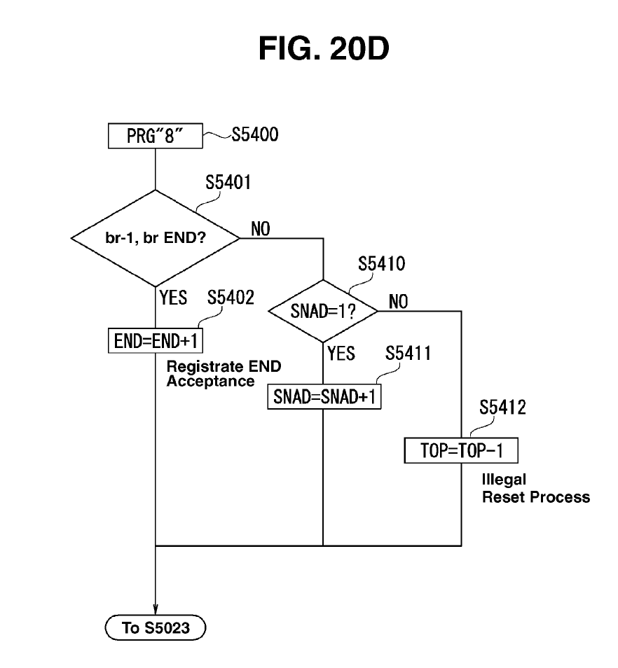

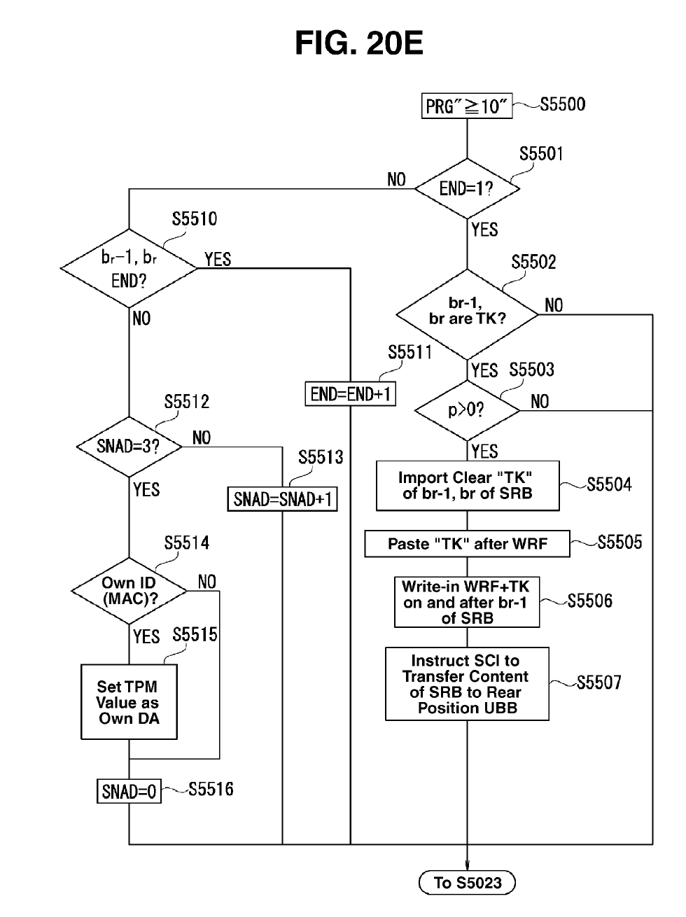

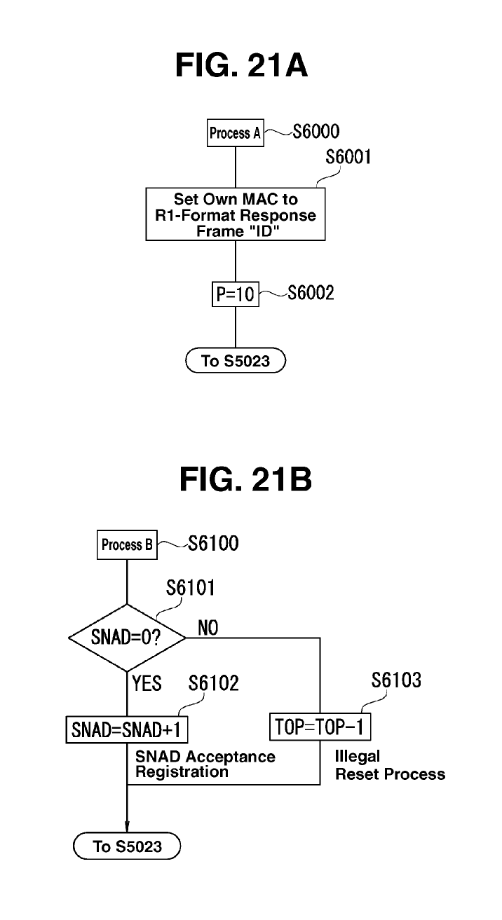

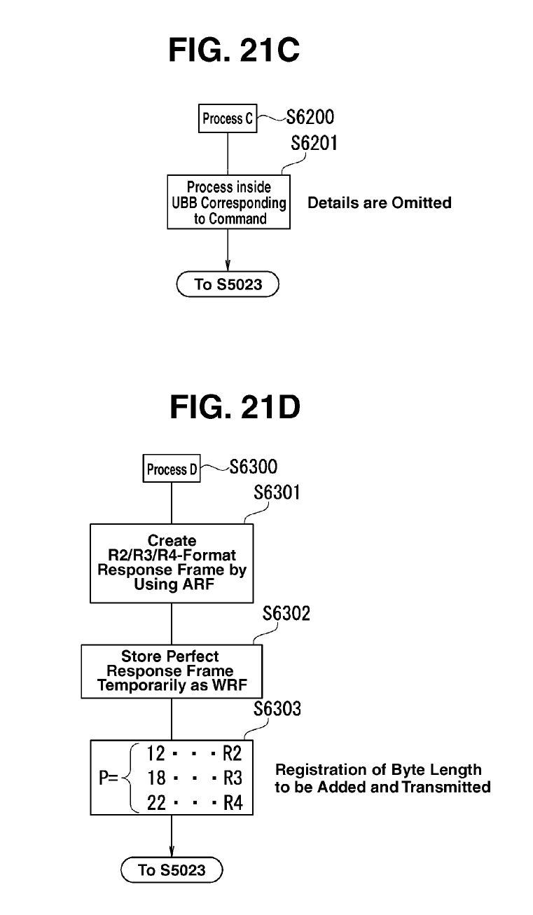

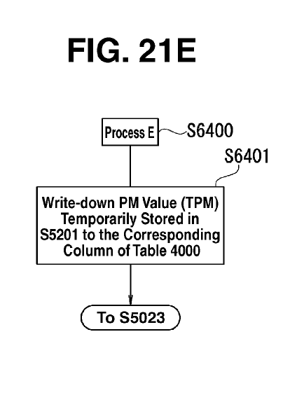

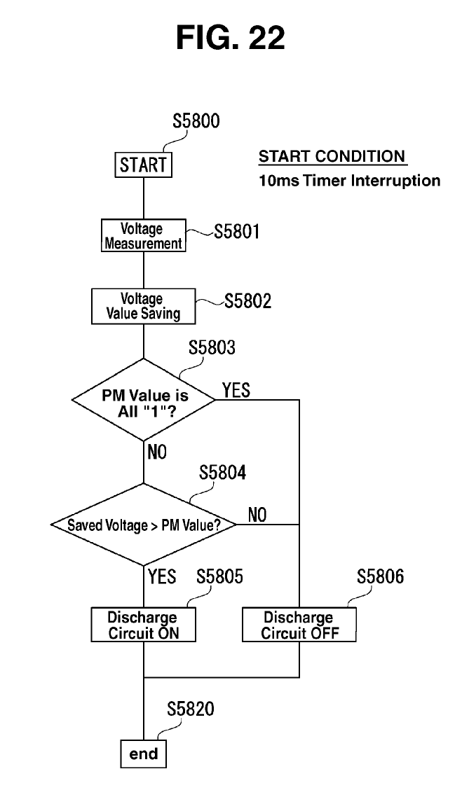

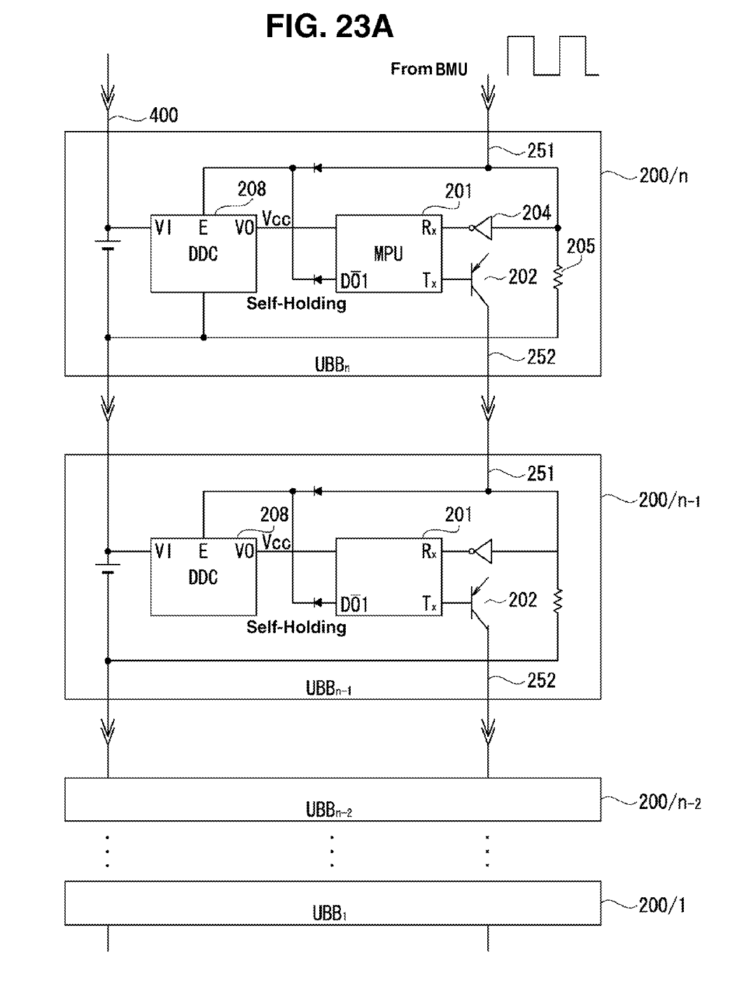

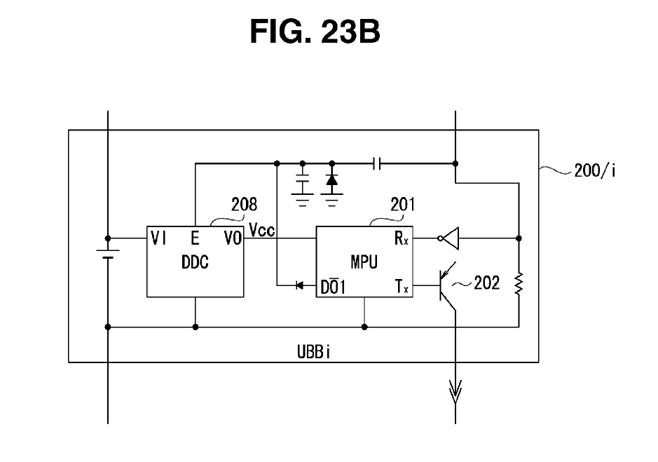

### DESCRIPTION OF REFERENCE NUMERALS

1: battery pack
100: battery management unit BMU
200/n: unit battery board UBB/n
201: micro-processor-unit MPU
202: driver switch for transmission signal
203: thermistor
204: inverter
205: resistor
206: electric current sensor
207: amplifier
208: DC-DC converter
251: signal reception line
252: signal transmission line
300, 301, 302, 310: communication channel
400: electric power line
500: unit battery
600: connector for signal line
700: connector for electric power line
801: U/B converter circuit
802: B/U converter circuit
1001: central processing unit CPU
1002: primary storage RAM
1003: serial communication interface SCI
1010: bus circuit
2010: bus circuit
2011: central processing unit CPU
2012: primary storage RAM
2013: serial communication interface SCI
2014: analog to digital converter ADC
2015: data control DATA
3000: measured value table
3100: measurement item
3200: measured value
4000: PM value import table
4100: import item
4200: import value
AD“ ”: analog to digital conversion port“ ”
ARF: arranged response frame
Er: battery nominal electromotive force
p: number of bytes to be added and transmitted
RBC: reception byte position counter
RBM: reception buffer memory
SBC: transmission byte position counter
SBM: transmission buffer memory
SBN: counter for counting the number of bytes necessary for transmission
SRB: transmission and reception buffer
WRF: transmission stand-by response frame

1. A battery pack constituted by connecting a plurality of unit batteries and including unit battery boards equipped with respective unit batteries and a battery management unit common to said plurality of unit battery boards as constituent elements thereof, characterized by comprising, for every individual unit battery board:
means for measuring, all of or a portion of, voltage of the equipped unit battery, temperature of said unit battery, ambient temperature of said unit battery and internal resistance of said unit battery, and for saving said measured value;
means for transmitting said saved measured value to said battery management unit as a digital signal; and
means for receiving a unit battery specifying voltage value which is transmitted as a digital signal from said battery management unit.

2. The battery pack according to claim 1, characterized in that
said plurality of unit battery boards and said battery management unit are connected by a single loop-shaped communication channel or a double loop-shaped communication channel, and
through said loop-shaped communication channel, there is carried out transmission and reception of said measured value, said unit battery specifying voltage value and relational control information between said respective unit battery boards and said battery management unit.

3. (canceled)

4. The battery pack according to claims 1 or 2, characterized in that
in each of the individual unit battery boards,
discharge of the battery cell inside said unit battery board is started in a case in which said saved measured value of the unit battery voltage is higher than said received unit battery specifying voltage value, and
the discharge of said battery cell is stopped or the stopping state thereof is made to continue in a case in which it is equivalent thereto or lower than that.

5. The battery pack according to claims 1 or 2, characterized in that
each of the unit battery boards
transfers all of said frame information directly to the rear position in a case in which the destination address of the frame to be transmitted from the front position is addressed to all of the unit battery boards and also the command of said frame is an information request command, and concurrently,
transmits the information to the rear position, after a token is detected, by inserting said requested information between the rearmost position of said frame and said detected token.

6. (canceled)

7. The battery pack according to claims 1 or 2, characterized in that
in order to collect, from all the unit battery boards, all of or a portion of unit battery voltage information, unit battery temperature information, unit battery internal resistance information, unit battery ambient temperature information and status information, said battery management unit
transmits a information requesting frame, which is addressed to all the unit battery boards or addressed to specified unit battery board, toward unit battery boards at one ends of a unit battery board group connected in a loop-shaped communication channel, and
receives said information of all the unit battery boards or of said specified unit battery board from the other ends of the unit battery boards.

8. (canceled)

9. (canceled)

10. The battery pack according to claims 1 or 2, characterized in that said battery management unit comprises:
means for analyzing voltage information, temperature information, internal resistance information or ambient temperature information of respective unit batteries, which are transmitted from the plurality of unit battery boards,
means for calculating a voltage value which said respective unit batteries should maintain, and
means for transmitting said voltage value, as the unit battery specifying voltage value, addressed to all the unit battery boards or addressed to a specific unit battery board.

11. The battery pack according to claim 1 or 2, characterized in that
the micro processor equipped in each of the unit battery boards comprises:
means for setting the data terminal to “high” immediately after receiving the power supply,
means for setting said data terminal to “low” when receiving a command from the battery management unit to the effect that the self-holding circuit is to be released;
the DC-DC converter, which is equipped in each of the unit battery boards, becomes in an operation state within the continuation of the “high” state of the data signal waveform to be transmitted at the enable terminal thereof from the battery management unit to the signal line connecting adjacent unit battery boards at the front position, and carries out power supply to said micro processor by generating output voltage;
immediately thereafter, said micro processor sets said data terminal to “high” depending on means for setting aforementioned data terminal to “high”, and forms an self-holding circuit of said DC-DC converter;
in addition, said micro processor releases the self-holding circuit of said DC-DC converter by setting said data terminal to “low” depending on means for setting said data terminal mentioned above to “low” when receiving the command from the battery management unit to the effect that the self-holding circuit is to be release; and
in that state, when the data signal waveform to be transmitted at the enable terminal thereof from the battery management unit to the signal line connecting the adjacent unit boards at the front position is held in the “low” state, said DC-DC converter stops the operation thereof, loses the output voltage, and the power supply to said micro processor stops.

12. The battery pack according to claim 11, characterized in that
the DC-DC converter becomes in an operation state when receiving a signal obtained by DC-restoring said data signal waveform at said enable terminal regardless of the continuation of the “high” state of the data signal waveform to be transmitted from the battery management unit to the signal line connecting the adjacent unit battery boards at the front position.

13. (canceled)

14. A software program for making a computer execute various kinds of means described in claim 10.

15. A software program for making a computer execute various kinds of means described in claim 11.
